(19) United States
(12) Patent Application Publication
(10) Pub. No.: US 2014/0045106 A1
(43) Pub. Date: Feb. 13, 2014

(54) COLORED CURABLE COMPOSITION FOR COLOR FILTER, COLORED CURED FILM, METHOD FOR PRODUCING COLOR FILTER, COLOR FILTER, AND DISPLAY DEVICE

(71) Applicant: FUJIFILM CORPORATION, Tokyo (JP)

(72) Inventors: Akinori FUJITA, Shizuoka-ken (JP); Kazumasa MOROZUMI, Shizuoka-ken (JP); Youhei ISHIJI, Shizuoka-ken (JP); Tomohiro KODAMA, Shizuoka-ken (JP)

(73) Assignee: FUJIFILM CORPORATION, Tokyo (JP)

(21) Appl. No.: 14/059,452

(22) Filed: Oct. 22, 2013

Related U.S. Application Data
(63) Continuation of application No. PCT/JP2012/061462, filed on Apr. 27, 2012.

(30) Foreign Application Priority Data
Apr. 28, 2011 (JP) 2011-101862

(51) Int. Cl. G02B 1/04; F21K 99/00; G03F 7/00

(52) U.S. Cl. CPC G02B 1/04; G03F 7/0007; F21K 9/50
USPC 430/7; 106/287.18; 430/270.1; 522/75; 522/65; 252/586; 362/97.1

(57) ABSTRACT

A colored curable composition is provided which includes (A) at least one colorant selected from the group consisting of a compound represented by the following formula (I) and a compound represented by the following formula (II); (B) a colorant having a hue different from that of the (A) colorant; and (C) a polymerizable compound. In the formulae, each of R¹ to R⁸ independently represents a hydrogen atom, an alkyl group, an alkoxy group, an alkoxycarbonyl group, a carbamoyl group, a sulfamoyl group, a sulfonylamino group, a carbonylamino group, a cyano group, an aryl group, or a heteroaryl group.

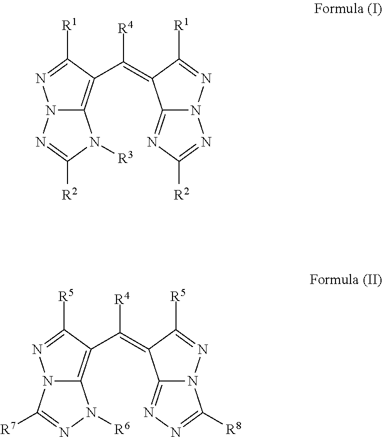

### CROSS-REFERENCE TO RELATED APPLICATIONS

This application is a continuation application of International Application No. PCT/JP2012/061462, filed Apr. 27, 2012, the disclosure of which is incorporated herein by reference in its entirety. Further, this application claims priority from Japanese Patent Application No. 2011-101862, filed Apr. 28, 2011, the disclosure of which is incorporated herein by reference in its entirety.

### TECHNICAL FIELD

The present invention relates to a colored curable composition for a color filter, a colored cured film formed using the colored curable composition for a color filter, a method for producing a color filter, a color filter including the colored cured film, and a display device including the color filter.

### BACKGROUND ART

Conventionally, in small-sized liquid crystal display devices and organic EL display devices, such as cellular phones, mobile game consoles, and PDAs, use of a backlight source is indispensible. The use of a backlight source has limitations due to the electric capacity of a secondary battery, a dry-cell battery, or the like that is a power source of the light source. As coloring materials of a color filter used in a display device that requires a backlight source, colorants that can provide a high degree of luminance and well transmit bright lines of the backlight to display colors have been favorably used.

In recent years, the size of liquid crystal display devices and organic EL display devices used for display monitors of personal computers or televisions has become increased, and more significance has been placed on color reproducibility in display devices having a large display screen than in display devices having a small display screen. Accordingly, the colorant used for a color filter is required to provide a higher level of image quality, that is, further improved color purity and contrast, in addition to improved luminance that has been required so far.

To meet the above demand, a color filter has been developed and commercialized in which colored patterns of red, green, blue, and the like are formed on a transparent substrate such as glass by a photolithography process using a colored curable composition prepared by adding an alkali-soluble resin, a polymerizable compound, a photopolymerization initiator, and other components to a pigment composition having a further smaller pigment particle size.

Meanwhile, for the improvement of color reproducibility, reduction of power consumption, and the like, development is in progress to employ a Light-Emitting Diode (LED) as a backlight source instead of the conventional Cold-Cathode Fluorescent Lamp (CCLF). The LED light source is better than the CCFL light source in terms of responsiveness, and has an excellent advantage in that it will not cause fear of environmental pollution since it is not necessary to use mercury as a raw material.

As the LED light source, for example, a white LED has been proposed which is obtained by combining a blue LED with a YAG phosphor for color mixing (for example, see Japanese Patent Application Laid-Open (JP-A) No. H06-75375 and JP-A No. 2008-292970). In this way, LED light sources that emit light of various colors by using various phosphors have been developed.

Also in the development of such LEDs, the improvement of color reproducibility and a high degree of luminance for reducing power consumption are required. However, if the color filter used with the CCFL that has been used conventionally is used as is with the white LED, since the characteristics of the light source are different, it is difficult to obtain a desired hue in a display device. Accordingly, in the current circumstances, development of a color filter having a hue matching the white LED is required.

Conventionally, in a pigment dispersion used as a main component for forming a hue by a colorant that is used in a colored curable composition (hereinafter, called a “resist composition” appropriately) for forming a colored region of a color filter, that is, in a pigment dispersion composition containing a pigment as a colorant, a pigment dispersant, and a dispersion medium, problems such as light scattering caused due to coarse pigment particles and viscosity increase caused due to defective dispersion stability are easily caused. Moreover, it is basically difficult to adjust a hue to obtain a desired hue by using pigments. Consequently, it has been difficult to obtain a pigment dispersion composition that realizes a hue suitable for a color filter that is used when the white LED is used as a backlight.

For this reason, regarding a color filter suitable for being used with the white LED, examination has been continuously conducted to use, as a colorant, a dye that exhibits a high degree of matching suitability to the white LED light source and facilitates hue adjustment. When a dye is used as a colorant, due to the color purity of the dye itself or the vividness of the hue thereof, the hue or the luminance of a display image can be improved when the image is displayed in a display device. In addition, there is no fear regarding coarse particles derived from a pigment, and there is an advantage that contrast can be improved.

As examples of dyes used in a colored curable composition for a color filter, compounds having various dye main structures have been proposed such as dipyrromethene dyes, pyrimidine azo dyes, pyrazole azo dyes, xanthene dyes, and triarylmethane dyes (for example, see JP-A No. 2008-292970, JP-A No. 2007-039478, JP-A No. H06-230210, and JP-A No. 2010-256598).

### SUMMARY OF INVENTION

### Technical Problem

However, when the known dyes described above are used as colorants, even if two or more kinds thereof are used concurrently, a hue as a green pixel suitable for a color filter is not obtained. Moreover, when the obtained colored pixel is combined with a backlight in which a white LED is used, desired color reproducibility is not achieved. Accordingly, there has been a demand for a colored curable composition that can provide a color filter having excellent hue, contrast, and luminance even when being applied not only to a backlight in which a CCFL is used but also to a backlight in which a white LED is used.

The present invention has been made in consideration of the above problems, and an object thereof is to provide a colored curable composition for a color filter that can form blue pixels having an excellent hue and a high degree of luminance even with a white LED light source. Moreover, another object of the present invention is to provide a colored cured film that is obtained using the colored curable composition and has excellent color characteristics, a method for producing the same, a color filter including the colored cured film, and a liquid crystal display device including the color filter.

### Solution to Problem

In order to solve the above problems, the present inventors have conducted thorough research. As a result, they have found that by the following means, that is, by using a dipyrazolotriazole compound having a specific symmetrical structure as a colorant, the above problems are solved, and made the present invention.

<1> A colored curable composition for a color filter, comprising:

(A) at least one colorant selected from the group consisting of a compound represented by the following formula (I) and a compound represented by the following formula (II):

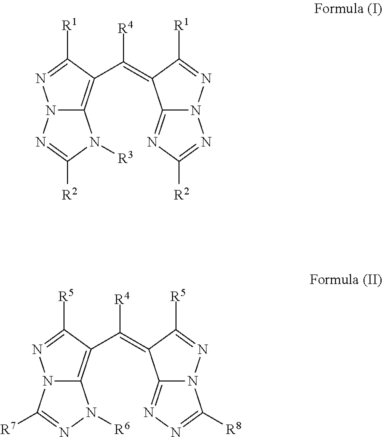

wherein, in formula (I), each of R¹, R², R³, and R⁴ independently represents a hydrogen atom, an alkyl group, an alkoxy group, an alkoxycarbonyl group, a carbamoyl group, a sulfamoyl group, a cyano group, an aryl group, or a heteroaryl group; plural R¹s present in a molecule may be the same as or different from each other; and plural R²s present in the molecule may be the same as or different from each other; and wherein, in formula (II), each of R⁴, R⁵, R⁶, R⁷, and R⁸ independently represents a hydrogen atom, an alkyl group, an alkoxy group, an alkoxycarbonyl group, a carbamoyl group, a sulfamoyl group, a sulfonylamino group, a carbonylamino group, a cyano group, an aryl group, or a heteroaryl group; and plural R⁵s present in a molecule may be the same as or different from each other;

(B) a colorant having a hue different from that of the (A) colorant; and

(C) a polymerizable compound.

<2> The colored curable composition for a color filter according to <1>, wherein a maximum absorption peak wavelength of the (B) colorant in a wavelength region of from 380 nm to 800 nm is within a range of from 500 nm to 800 nm.

<3> The colored curable composition for a color filter according to <1> or <2>, wherein the (B) colorant is a zinc phthalocyanine compound represented by the following formula (III):

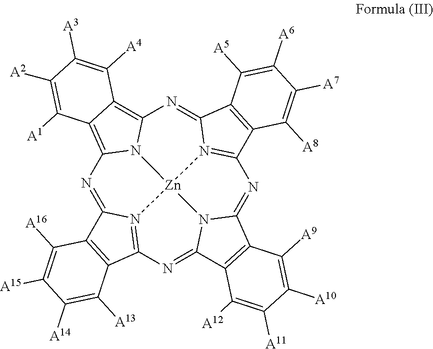

wherein, in formula (III), each of A¹, A², A³, A⁴, A⁵, A⁶, A⁷, A⁸, A⁹, A¹⁰, A¹¹, A¹², A¹³, A¹⁴, A¹⁵, and A¹⁶ independently represents a halogen atom, an alkyl group, an alkoxy group, or a thioalkoxy group.

<4> The colored curable composition for a color filter according to any one of <1> to <3>, wherein the (B) colorant is a halogenated phthalocyanine zinc complex compound.

<5> The colored curable composition for a color filter according to any one of <1> to <4>, further comprising (D) a photopolymerization initiator.

<6> The colored curable composition for a color filter according to <5>, wherein the (D) photopolymerization initiator is an oxime compound.

<7> The colored curable composition for a color filter according to any one of <1> to <6>, further comprising an aliphatic polyfunctional mercapto compound.

<8> The colored curable composition for a color filter according to any one of <1> to <7>, wherein the compound represented by formula (I) is a compound represented by the following formula (IV):

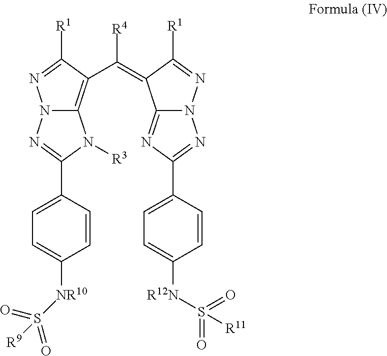

wherein, in formula (IV), R¹, R³, and R⁴ have the same definitions as R¹, R³, and R⁴ in formula (I), respectively; each of R⁹ and R¹¹ independently represents an alkyl group, an aryl group, or a heteroaryl group; and each of R¹⁰ and R¹² independently represents a hydrogen atom or an alkyl group.

<9> The colored curable composition for a color filter according to any one of <1> to <7>, wherein the compound represented by formula (II) is a compound represented by the following formula (V):

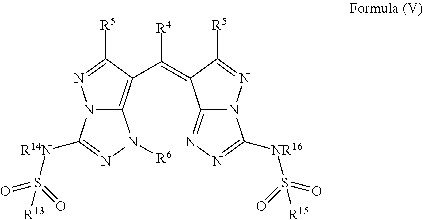

wherein, in formula (V), R⁴, R⁵, and R⁶ have the same definitions as R⁴, R⁵, and R⁶ in formula (II), respectively; each of R¹³ and R¹⁵ independently represents an alkyl group, an aryl group, or a heteroaryl group; and each of R¹⁴ and R¹⁶ independently represents a hydrogen atom or an alkyl group.

<10> A colored cured film, formed from the colored curable composition according to any one of <1> to <9>.

<11> A method for producing a color filter, comprising:

a step of applying the colored curable composition according to any one of <1> to <9> onto a substrate to form a colored curable composition layer; and

a step of patternwise exposing and developing the formed colored curable composition layer.

<12> A color filter, comprising the colored cured film according to <10>.

<13> A color filter, produced by the method for producing a color filter according to <11>.

<14> A display device, comprising the color filter according to <12> or <13>.

<15> The display device according to <14>, further comprising an LED backlight having a peak wavelength of light emission intensity within a wavelength range of from 430 nm to 470 nm.

The colored curable composition of the present invention contains, as a colorant, at least one kind of colorant [hereinafter, sometimes called “(A) a specific colorant”] selected from a compound represented by formula (I) and a compound represented by formula (II).

The (A) specific colorant according to the present invention has a yellow hue, and exhibits a sharp absorption spectrum from 450 nm to 500 nm. Therefore, this colorant has a characteristic of being able to form a color filter that exhibits a high degree of color purity and luminance. Presumably, this characteristic may be an effect resulting from the fact that a molecular structure of the (A) specific colorant has a high degree of rigidity.

In a color filter with which a white LED is used, since there is no bright line of 480 nm caused by the light source, even if only a small amount of a yellow colorant is added to green pixels, an excellent hue can be expressed. Accordingly, due to the molecular structure of the (A) specific colorant according to the present invention, the solubility thereof is slightly lower than that of other colorants having the same or similar main skeleton, but the specific colorant exhibits its performance sufficiently even with the solubility thereof. It is therefore considered that a colored cured film for a color filter that accomplishes a higher degree of color purity and a higher degree of luminance can be provided, compared to a case where other colorants that have a higher solubility and have the same or similar main skeleton are used.

Moreover, in the present invention, the (A) specific colorant has a narrow absorption spectrum due to its rigid structure, has a low fluorescence intensity, and can realize high contrast. It is generally known that when a dye shows a narrow absorption spectrum due to the rigid structure thereof, the fluorescence intensity increases due to the rigidity thereof. However, since the (A) specific colorant according to the present invention has N—N hetero bonds in a molecule, excitation energy is efficiently deactivated by thermal vibration of the N—N bonds. Accordingly, the (A) specific colorant has a characteristic of having a low fluorescence intensity while having a narrow absorption spectrum, and exhibits an excellent performance to achieve both high luminance and high contrast.

### Advantageous Effects of Invention

According to the present invention, it is possible to provide a colored curable composition for a color filter that can form blue pixels having an excellent hue and a high degree of luminance even with a white LED light source. Further, according to the present invention, it is possible to provide a colored cured film that is obtained using the colored curable composition and has excellent color characteristics, a method for producing the same, a color filter including the colored cured film, and a liquid crystal display device including the color filter.

### DESCRIPTION OF EMBODIMENTS

Hereinafter, the colored curable composition, the color filter, the method for producing a color filter, and the display device in which the color filter is used according to the present invention will be described in detail.

Moreover, in the present specification, when a substituent (atomic group) is described without a description regarding whether it is substituted or unsubstituted, this term is used in the sense that both an unsubstituted group and a group further having a substituent are included, unless otherwise specified. For example, when “alkyl group” is described, this term is used in the sense that both an unsubstituted alkyl group and an alkyl group further having a substituent are included. This will be applied to other substituents (atomic groups) in the same manner.

In the present specification, a numerical range described using “to” means a range including the numerical values described before and after “to” as a lower limit and an upper limit.

In the present specification, a total solid content refers to a total mass of components that remain after a solvent is excluded from all components of the colored curable composition.

Further, in the present specification, “(meth)acrylate” represents either or both of acrylate and methacrylate, “(meth)acryl” represents either or both of acryl and methacryl, and “(meth)acryloyl” represents either or both of acryloyl and methacryloyl.

In addition, in the present specification, a “monomer” has the same definition as a “monomer”. The monomer in the present specification is distinguished from an oligomer and a polymer and refers to a compound having a weight average molecular weight of 2,000 or less. In the present specification, a polymerizable compound refers to a compound having a polymerizable functional group, and may be a monomer or a polymer. The polymerizable functional group refers to a group that is involved in a polymerization reaction.

In the present specification, the term “step” includes not only an independent step, but also a step that is not clearly distinguished from other steps, as long as a desired action of the step is achieved.

<Colored Curable Composition for a Color Filter>

The colored curable composition of the present invention contains at least (A) at least one kind of colorant selected from a compound represented by the following formula (I) and a compound represented by the following formula (II), (B) a colorant having a hue (structure) different from that of the (A) colorant, and (C) a polymerizable compound.

Hereinafter, the respective components contained in the colored curable composition for a color filter of the present invention will be described.

<Component (A): At Least One Kind of Colorant (Specific Colorant) Selected from a Compound Represented by Formula (I) and a Compound Represented by the Following Formula (II)>

The colored curable composition of the present invention contains at least one kind of colorant [(A) specific colorant] selected from compounds represented by the following formula (I) and compounds represented by the following formula (II). The (A) specific colorant is a colorant having a yellow hue.

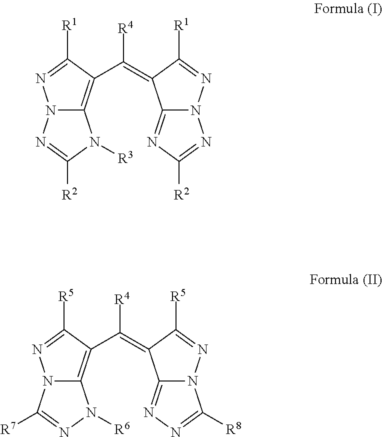

In formula (I), each of R¹, R², R³, and R⁴ independently represents a hydrogen atom, an alkyl group, an alkoxy group, an alkoxycarbonyl group, a carbamoyl group, a sulfamoyl group, a cyano group, an aryl group, or a heteroaryl group, plural R¹s present in a molecule may be the same as or different from each other, and plural R²s present in the molecule may be the same as or different from each other.

In formula (II), each of R⁴, R⁵, R⁶, R⁷, and R⁸ independently represents a hydrogen atom, an alkyl group, an alkoxy group, an alkoxycarbonyl group, a carbamoyl group, a sulfamoyl group, a sulfonylamino group, a carbonylamino group, a cyano group, an aryl group, or a heteroaryl group, and plural R⁵s present in a molecule may be the same as or different from each other.

The substituents that are more preferable as the structure for the (A) specific colorant will be described. As R¹ in formula (I) and R⁵ in formula (II), an alkyl group, an aryl group, or a cyano group is preferable, and the alkyl group and aryl group may further have a substituent. Herein, examples of the substituent that can be introduced into the alkyl group and aryl group include an alkoxy group, a thioalkoxy group, a cyano group, a halogen atom, and the like.

More preferable examples of R¹ and R⁵ include a t-butyl group, a phenyl group, and an o-methylphenyl group.

R³ in formula (I) is more preferably a hydrogen atom, R⁴ in formulae (I) and (II) is preferably a hydrogen atom or a methyl group, and more preferably a hydrogen atom.

Each of R², R⁷, and R⁸ may be any one of a hydrogen atom, an alkyl group, an alkoxy group, an alkoxycarbonyl group, a carbamoyl group, a sulfamoyl group, a sulfonylamino group, a carbonylamino group, a cyano group, an aryl group, and a heteroaryl group. However, each of R², R⁷, and R⁸ is preferably an alkoxycarbonyl group, a carbamoyl group, a sulfamoyl group, a sulfonylamino group, or a carbonylamino group having a partial structure selected from a substituted alkyl group, a PEO chain (polyethylene glycol), a PPO chain (polypropylene glycol), an ammonium salt, and a polymerizable group in the structure thereof, and more preferably a sulfonylamino group having the above partial structure. Plural R²s present in a molecule may be the same as or different from each other, but in view of synthesis suitability, R^{2s} are preferably the same as each other.

In a more preferable embodiment, among the (A) specific colorants, the compound represented by formula (I) is a compound represented by the following formula (IV), and the compound represented by formula (II) is a compound represented by the following formula (V).

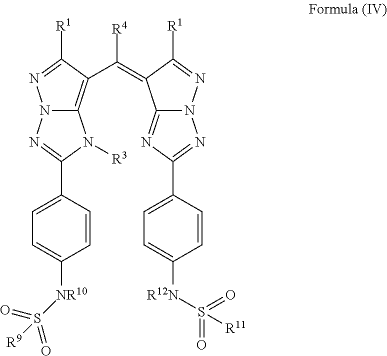

In formula (IV), R¹, R³, and R⁴ have the same definitions as R¹, R³, and R⁴ in formula (I), respectively, and preferable examples thereof are also the same. Each of R⁹ and R¹¹ independently represents an alkyl group, an aryl group, or a heteroaryl group, and each of R¹⁰ and R¹² independently represents a hydrogen atom, a methyl group, or an ethyl group.

Each of R¹⁰ and R¹² is preferably a hydrogen atom. Each of R⁹ and R¹¹ is preferably a substituted or unsubstituted alkyl group. Alternatively, each of R⁹ and R¹¹ is preferably an alkyl group, an aryl group, or a heteroaryl group having a partial structure selected from a PEO chain (polyethylene glycol), a PPO chain (polypropylene glycol), an ammonium salt, and a polymerizable group, and more preferably an alkyl group having 2 to 8 carbon atoms or a substituted alkyl group having a (meth)acrylic group on an alkyl chain.

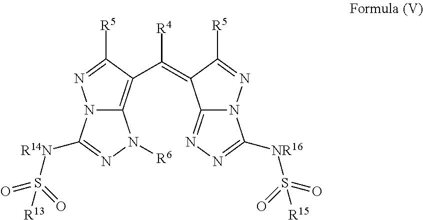

In formula (V), R⁴, R⁵, and R⁶ have the same definitions as R⁴, R⁵, and R⁶ in formula (II), respectively, and preferable examples thereof are also the same. Each of R¹³ and R¹⁵ independently represents an alkyl group, an aryl group, or a heteroaryl group, and each of R¹⁴ and R¹⁶ independently represents a hydrogen atom, a methyl group, or an ethyl group.

Each of R¹⁴ and R¹⁶ is preferably a hydrogen atom. R¹³ and R¹⁵ are preferably a substituted alkyl group. Alternatively, R¹³ and R¹⁵ are preferably an alkyl group, an aryl group, or a heteroaryl group having a partial structure selected from a PEO chain (polyethylene glycol), a PPO chain (polypropylene glycol), an ammonium salt, and a polymerizable group, and more preferably an alkyl group having 2 to 8 carbon atoms or a substituted alkyl group having a (meth)acrylic group on an alkyl chain.

Specific examples of the (A) specific colorant used in the present invention will be shown below.

Examples of the colorant represented by formula (I) and the colorant that is a preferable embodiment thereof and represented by formula (IV) include the following Example compounds (B-1) to (B-8). Examples of the colorant represented by formula (II) or the colorant that is a preferable embodiment thereof and represented by formula (V) include (B-9) to (B-15). However, the present invention is not limited to these.

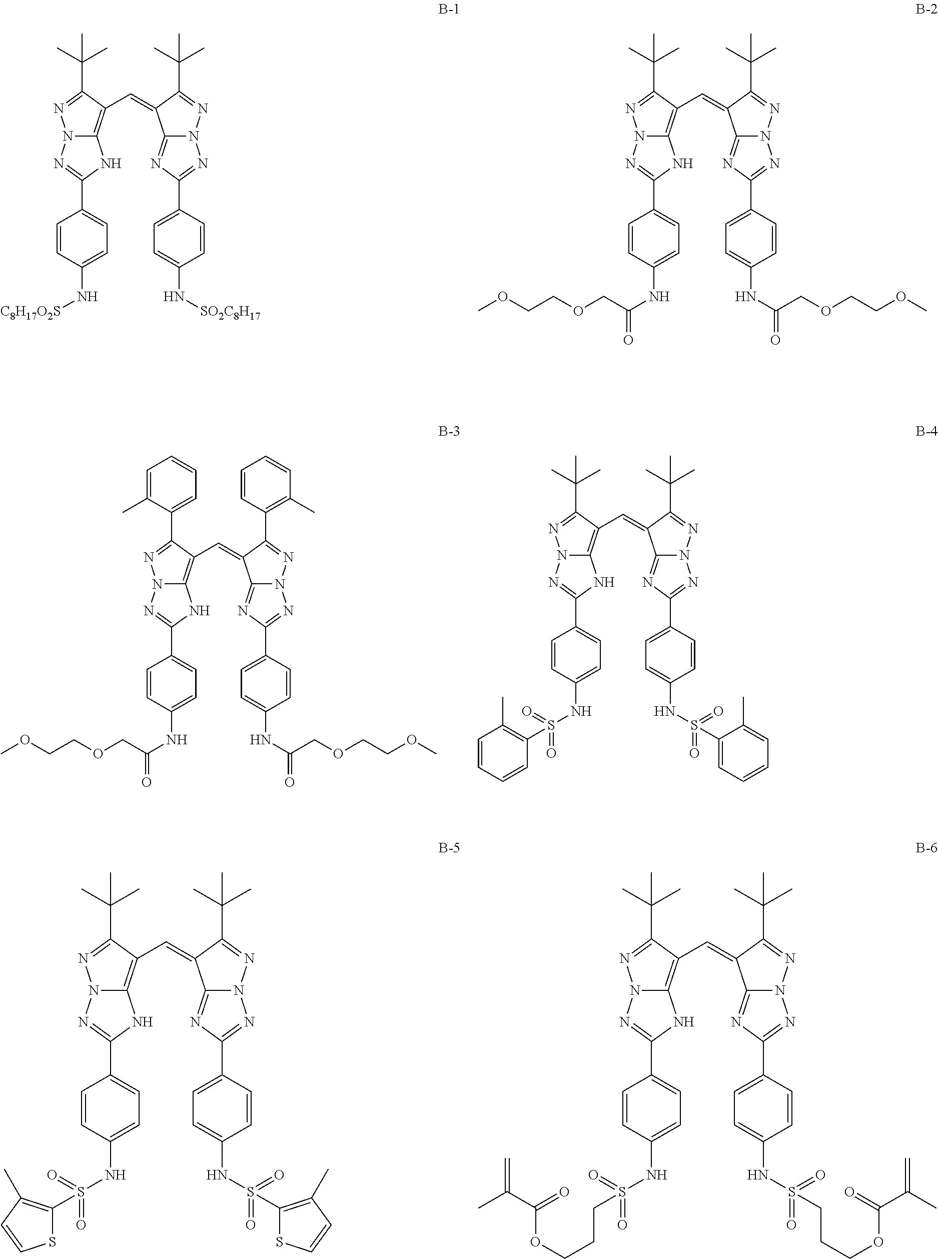

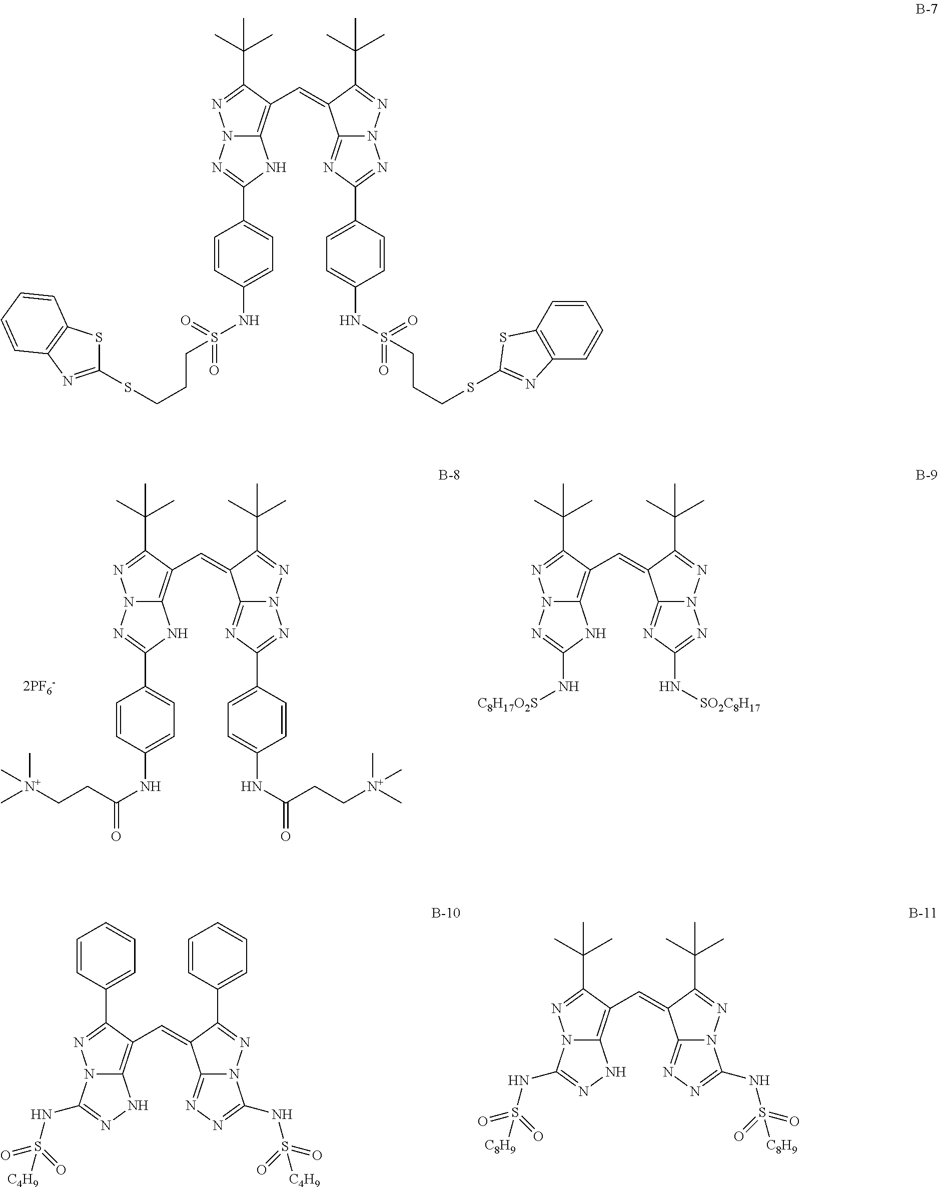

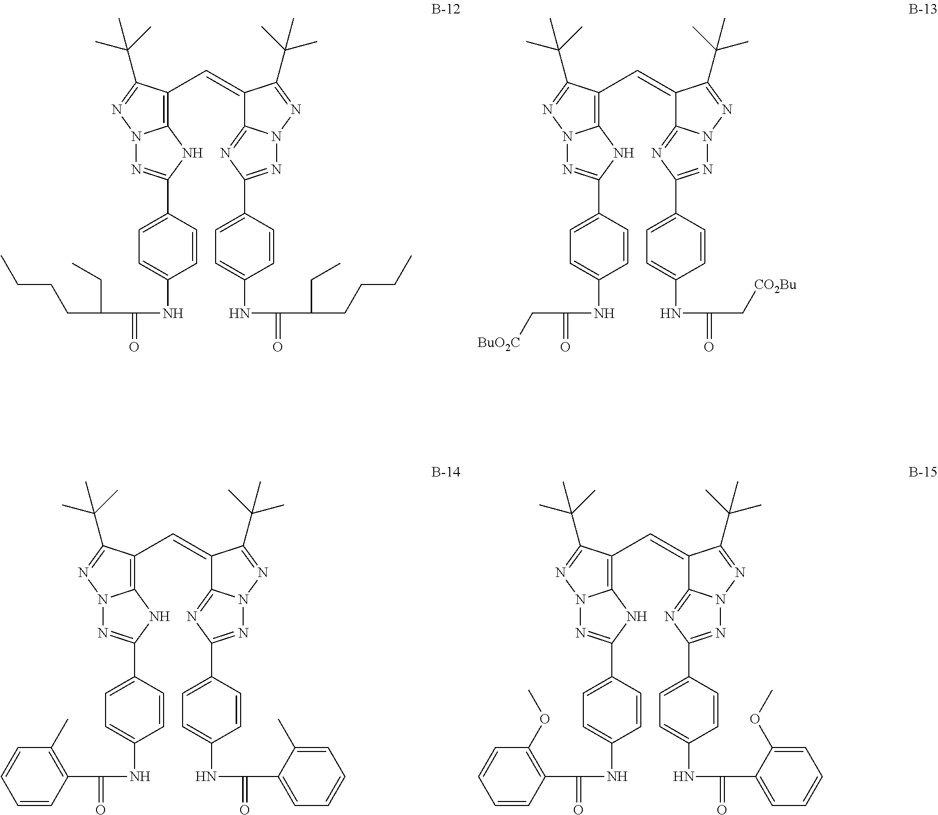

The colored curable composition of the present invention may contain only one kind of the (A) specific colorant, or contain two or more kinds thereof concurrently.

The content of the (A) specific colorant in the colored curable composition of the present invention is appropriately selected according to the purpose. However, when the composition is used for forming colored pixels of a color filter, the content is preferably 0.5% by mass to 70% by mass, and more preferably 10% by mass to 40% by mass, based on the total solid content of the colored curable composition.

<Component (B): Colorant Having Hue Different from that of the (A) Specific Colorant>

The colored curable composition of the present invention contains, in addition to the (A) specific colorant, a colorant [hereinafter, called “(B) another colorant” appropriately] that differs from the (A) specific colorant in terms of the structure and hue. The (B) another colorant may be selected from known dyes that absorb light in a visible light wavelength region, dye derivatives, pigments, and pigment dispersions.

Moreover, the (A) specific colorant has a maximum absorption peak wavelength (λmax) in a range of from 420 nm to 480 nm. Therefore, the (B) another colorant refers to a colorant having a maximum absorption peak wavelength of less than 420 nm or more than 480 nm in a visible light wavelength region that is from 380 nm to 800 nm. That is, it refers to a colorant having a hue different from that of the (A) specific colorant.

In the present specification, a dye solution or a pigment dispersion containing a colorant to be measured is prepared at a concentration that enables measurement (for example, a concentration that yields an absorbance of 0.8 to 1.0) by using a solvent, and a maximum absorption peak wavelength of the colorant is measured by using a CARY 5/UV-visible spectrophotometer (commercially available product: manufactured by Varian Medical Systems, Inc.), and the obtained value is employed.

A dye compound that is used as the (B) another colorant and differs from the (A) specific colorant in terms of the hue and structure may have any structure as long as it does not influence the hue of the colored image, and examples thereof include anthraquinone-based dyes (for example, anthraquinone compounds described in JP-A No. 2001-10881), phthalocyanine-based dyes (for example, phthalocyanine compounds described in US Patent No. 2008/0076044A1, xanthene-based dyes (for example, C. I. Acid Red 289), triarylmethane-based dyes (for example, C. I. Acid Blue 7), C. I. Acid Blue 83, C. I. Acid Blue 90, C I. Solvent Blue 38, C. I. Acid Violet 17, C. I. Acid Violet 49, C. I. Acid Green 3, methine dyes, and the like.

Examples of the pigment compound that is used as the (B) another colorant and has a hue different from that of the (A) colorant include perylene, perinone, quinacridone, quinacridone quinone, anthraquinone, anthanthrone, benzimidazolone, disazo condensation, disazo, azo, indanthrone, phthalocyanine, triaryl carbonium, dioxazine, aminoanthraquinone, diketopyrrolopyrrole, indigo, thioindigo, isoindoline, isoindolinone, pyranthrone, isoviolanthrone, and the like. More specific examples of these include perylene compound pigments such as Pigment Red 190, Pigment Red 224, and Pigment Violet 29, perinone compound pigments such as Pigment Orange 43 and Pigment Red 194, quinacridone compound pigments such as Pigment Violet 19, Pigment Violet 42, Pigment Red 122, Pigment Red 192, Pigment Red 202, Pigment Red 207, and Pigment Red 209, quinacridone quinone compound pigments such as Pigment Red 206, Pigment Orange 48, and Pigment Orange 49, anthraquinone compound pigments such as Pigment Yellow 147, anthanthrone compound pigments such as Pigment Red 168, benzimidazolone compound pigments such as Pigment Brown 25, Pigment Violet 32, Pigment Orange 36, Pigment Yellow 120, Pigment Yellow 180, Pigment Yellow 181, Pigment Orange 62, and Pigment Red 185, disazo condensation compound pigments such as Pigment Yellow 93, Pigment Yellow 94, Pigment Yellow 95, Pigment Yellow 128, Pigment Yellow 166, Pigment Orange 34, Pigment Orange 13, Pigment Orange 31, Pigment Red 144, Pigment Red 166, Pigment Red 220, Pigment Red 221, Pigment Red 242, Pigment Red 248, Pigment Red 262, and Pigment Brown 23,

disazo compound pigments such as Pigment Yellow 13, Pigment Yellow 83, and Pigment Yellow 188, azo compound pigments such as Pigment Red 187, Pigment Red 170, Pigment Yellow 74, Pigment Yellow 150, Pigment Red 48, Pigment Red 53, Pigment Orange 64, and Pigment Red 247, indanthrone compound pigments such as Pigment Blue 60, phthalocyanine compound pigments such as Pigment Green 7, Pigment Green 36, Pigment Green 37, Pigment Green 58, Pigment Blue 16, Pigment Blue 75 and Pigment Blue 15, triaryl carbonium compound pigments such as Pigment Blue 56 and Pigment Blue 61, dioxazine compound pigments such as Pigment Violet 23 and Pigment Violet 37, aminoanthraquinone compound pigments such as Pigment Red 177, diketopyrrolopyrrole compound pigments such as Pigment Red 254, Pigment Red 255, Pigment Red 264, Pigment Red 272, Pigment Orange 71, and Pigment Orange 73, thioindigo compound pigments such as Pigment Red 88, isoindoline compound pigments such as Pigment Yellow 139 and Pigment Orange 66, isoindolinone compound pigments such as Pigment Yellow 109 and Pigment Orange 61, pyranthrone compound pigments such as Pigment Orange 40 and Pigment Red 216, and isoviolanthrone compound pigments such as Pigment Violet 31.

As the (B) another colorant that is used in combination with the (A) specific colorant having a yellow hue, that is, a maximum absorption peak wavelength (λmax) in a range of from 420 nm to 480 nm, in view of suitability thereof for a color filter, a colorant having a maximum absorption peak wavelength in a wavelength region of 500 nm to 800 nm in a wavelength region of 380 nm to 800 nm is preferable, and a colorant having a maximum absorption peak wavelength in a wavelength region of 550 nm to 700 nm is more preferable. A colorant having a green hue, that is, a maximum absorption peak wavelength in a wavelength region of 600 nm to 700 nm is the most preferable. Specific examples of the colorant having a maximum absorption peak wavelength in the above wavelength region include Pigment Green 36, Pigment Green 58, and the like.

Moreover, if structure of the preferable pigment is focused on, examples of the (B) another colorant preferably include a zinc phthalocyanine compound represented by the following formula (III).

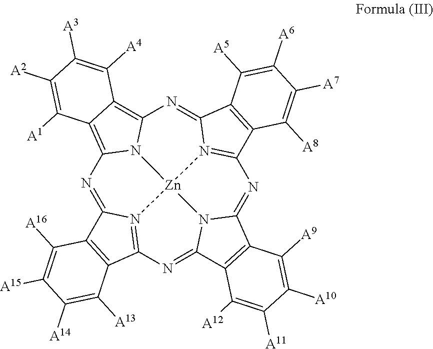

In formula (III), each of A¹, A², A³, A⁴, A⁵, A⁶, A⁷, A⁸, A⁹, A¹⁰, A¹¹, A¹², A¹³, A¹⁴, A¹⁵, and A¹⁶ independently represents a halogen atom, an alkyl group, an alkoxy group, or a thioalkoxy group.

In formula (III), it is preferable that each of A¹ to A¹⁶ independently represent a hydrogen atom, a chlorine atom, or a bromine atom, and it is preferable that at least eight of them are bromine atoms.

In the zinc phthalocyanine compound, if eight or more of A¹ to A¹⁶ are bromine atoms, yellowish green with high brightness is exhibited, and this is optimal to be used for forming a green pixel portion of a color filter. As the (B) another colorant of the present invention, a zinc phthalocyanine compound having ten or more bromine atoms is the most preferable.

The average composition of the zinc phthalocyanine compound can be easily determined by mass spectrometry based on mass spectroscopy and halogen content analysis by flask combustion ion chromatography.

The zinc phthalocyanine compound can be produced by known production methods, for example, a chlorosulfonic acid process, a halogenated phthalonitrile process, and a melting process. More specifically, the production methods are described in JP-A No. 2008-19383, JP-A No. 2007-320986, JP-A No. 2004-70342, and the like in more detail.

Further, the pigment known as C. I. Pigment Green 58 is also included in the brominated phthalocyanine pigment in the present invention.

It is preferable that the zinc phthalocyanine compound used for the colored curable composition for a color filter have an average primary particle size within a range of 10 nm to 40 nm. If the zinc phthalocyanine compound having an average primary particle size within the above range is used with the (A) specific colorant, it is possible to obtain a colored curable composition for a color filter that has excellent dispersion stability and coloring ability and high luminance and contrast.

Particles in a visual field are imaged using a transmission electron microscope, and for 100 primary particles of the zinc phthalocyanine-based pigment that constitute aggregates on the two-dimensional image, the average values of long diameters (major axes) and short diameters (minor axes) thereof are determined respectively. The average value of the average values is the average primary particle size in the present invention.

In order to obtain a zinc phthalocyanine-based pigment having an average primary particle size within a range of 10 nm to 40 nm, any method may be used to obtain the fine particles. However, in view of easily inhibiting crystal growth and obtaining pigment particles having a relatively small average primary particle size, it is preferable to employ solvent salt milling treatment. In addition, the brominated zinc phthalocyanine pigment having an average primary particle size within a range of 10 nm to 40 nm is commercially available and can be purchased from DIC Corporation.

When a pigment is used as the (B) another colorant, it is preferable that a pigment dispersion is prepared in advance and used. The pigment dispersion can be prepared according to the disclosure of, for example, JP-A No. H09-197118 or JP-A No. 2000-239544.

When a dye or a pigment is used as the (B) another colorant, it may be used in a content within a range that does not diminish the effects of the present invention. The content is preferably 0.5% by mass to 70% by mass, based on a total solid content of the colored curable composition of the present invention. When the (B) another colorant is used, it is used in a proportion of 20 parts by mass to 500 parts by mass, based on 100 parts by mass of the (A) specific colorant.

<Component (C): Polymerizable Compound>

The colored curable composition of the present invention contains at least one kind of polymerizable compound. Examples of the polymerizable compound include addition-polymerizable compounds having at least one ethylenically unsaturated double bond.

As the polymerizable compound having at least one ethylenically unsaturated double bond, that selected from known components can be used, and specific examples thereof include the components described in Paragraphs [0010] to [0020] of JP-A No. 2006-23696 and the components described in Paragraphs [0027] to [0053] of JP-A No. 2006-64921.

Regarding the (C) polymerizable compound, the structure thereof, whether it is used alone or used concurrently, and details of how to use it including the amount thereof used can be arbitrarily set according to how the final performance of the colored curable composition will be designed. For example, in view of sensitivity, a structure that contains a large amount of unsaturated groups per molecule is preferable, and in many cases, a bi- or higher functional structure is preferable. Moreover, in view of enhancing the strength of the colored cured film, a tri- or higher functional structure is preferable. In addition, a method that regulates both the sensitivity and strength by concurrently using compounds having different number of functional groups or having different polymerizable groups (for example, acrylic acid ester, methacrylic acid ester, styrene-based compounds, and vinylether-based compounds) is also effective. Furthermore, for the compatibility with other components (for example, a photopolymerization initiator, colorants (pigments), and a binder polymer) contained in the colored curable composition and dispersibility, selection and the method of use of the polymerizable compound are important factors. For example, in some cases, compatibility can be improved by using a low-purity compound or concurrently using two or more kinds thereof. In addition, in view of improving adhesiveness to a hard surface of a substrate or the like, a specific structure can also be selected.

As the polymerizable compound, a urethane addition-polymerizable compound that is produced using an addition reaction between isocyanate and a hydroxyl group is also preferable. Moreover, urethane acrylates described in JP-A No. S51-37193, Japanese Examined Patent Application Publication (JP-B) No. H2-32293, and JP-B No. H2-16765, and urethane compounds having an ethylene oxide skeleton that are described in JP-B No. 558-49860, JP-B No. S56-17654, JP-B No. S62-39417, and JP-B No. S62-39418 are also preferable.

Examples of the compound also include polyester acrylates described in JP-A No. S48-64183, JP-B No. S49-43191, and JP-B No. S52-30490 respectively, and polyfunctional acrylates or methacrylates, such as epoxy acrylates obtained by reacting an epoxy resin with (meth)acrylic acid. Moreover, the compounds introduced as photocurable monomers and oligomers in the Journal of Adhesion Society of Japan, Vol. 20, No. 7, pp 300-308 (1984) can also be used.

Specific examples thereof include pentaerythritol tri(meth)acrylate, pentaerythritol tetra(meth)acrylate, dipentaerythritol penta(meth)acrylate, dipentaerythritol hexa(meth)acrylate, tri((meth)acryloyloxyethyl)isocyanurate, a pentaerythritol tetra(meth)acrylate EO modified product, a dipentaerythritol hexa(meth)acrylate EO modified product, and the like. Preferable examples of commercially available products thereof include NK ESTER A-TMMT, NK ESTER A-TMM-3, NK OLIGO UA-32P, and NK OLIGO UA-7200 (all manufactured by SHIN-NAKAMURA CHEMICAL CO., LTD.), ARONIX M-305, ARONIX M-306, ARONIX M-309, ARONIX M-450, ARONIX M-402, and TO-1382 (all manufactured by TOAGOSEI CO., LTD.), V#802 (manufactured by OSAKA ORGANIC CHEMICAL INDUSTRY LTD.), KAYARAD D-330, KAYARAD D-320, KAYARAD D-310, and KAYARAD DPHA (all manufactured by NIPPON KAYAKU Co., Ltd.), and the like.

Moreover, two or more kinds of polymerizable compounds may be used concurrently. For example, in view of curing exposure sensitivity and developability adjustment, it is preferable to use dipentaerythritol hexaacrylate in combination with an EO modified product such as a pentaerythritol tetra(meth)acrylate EO modified product or a dipentaerythritol hexa(meth)acrylate EO modified product. These combinations can further improve patterning suitability.

The colored curable composition may contain only one kind of the polymerizable compound, or as described above, two or more kinds thereof may be used concurrently according to the purpose.

The content of the (C) polymerizable compound in a total solid content of the colored curable composition, and a total content of the plural kinds of the (C) polymerizable compound in a total solid content of the colored curable composition at the time when the composition contains two or more kinds of the (C) polymerizable compounds are appropriately selected without particular limitation. However, in view of more markedly exerting the effects of the present invention, the content is preferably 10% by mass to 80% by mass, more preferably 15% by mass to 75% by mass, and particularly preferably 20% by mass to 60% by mass.

The colored curable composition of the present invention may optionally further contain various additives such as a photopolymerization initiator, a colored compound, an organic solvent, a crosslinking agent, a surfactant, a filler, an antioxidant, a UV absorber, an aggregation inhibitor, a sensitizer, and a light stabilizer.

<Component (D): Photopolymerization Initiator>

It is preferable for the colored curable composition of the present invention to contain at least one kind of photopolymerization initiator. The photopolymerization initiator can be selected, without particular limitation, in consideration of the characteristics, efficiency of generating an initiation species, absorption wavelength, availability, cost, and the like, as long as it makes it possible to polymerize the (C) polymerizable compound.

The photopolymerization initiators are compounds that are sensitive to light for exposure and initiate and promote polymerization of a polymerizable compound. Among these, compounds that are sensitive to actinic rays having a wavelength of 300 nm or longer and initiate and promote polymerization of a polymerizable compound are preferable. Moreover, a photopolymerization initiator that is not sensitive directly to actinic rays having a wavelength of 300 nm or longer can also be preferably used when being combined with a sensitizer.

Examples of the photopolymerization initiator include at least one active halogen compound selected from a halomethyl oxadiazole compound and a halomethyl-s-triazine compound, a 3-aryl-substituted coumarin compound, a lophine dimer, a benzophenone compound, an acetophenone compound and a derivative thereof, a cyclopentadiene-benzene-iron complex and a salt thereof, an oxime-based compound, and the like. Specific examples of the photopolymerization initiator include those described in Paragraphs [0070] to [0077] of JP-A No. 2004-295116. Among these, an organic halogenated compound, a hexaarylbiimidazole compound, an oxime-based compound, and the like are preferable, and in view of the rapidness of a polymerization reaction, an oxime-based compound is preferable.

The oxime-based compound (hereinafter, also called an “oxime-based photopolymerization initiator”) is not particularly limited, and examples thereof include the oxime-based compounds described in JP-A No. 2000-80068, WO02/100903A1, JP-A No. 2001-233842, and the like.

Specific examples thereof include 2-(O-benzoyloxime)-1-[4-(phenylthio)phenyl]-1,2-butanedione, 2-(O-benzoyloxime)-1-[4-(phenylthio)phenyl]-1,2-pentanedione, 2-(O-benzoyloxime)-1-[4-(phenylthio)phenyl]-1,2-hexanedione, 2-(O-benzoyloxime)-1-[4-(phenylthio)phenyl]-1,2-heptanedione, 2-(O-benzoyloxime)-1-[4-(phenylthio)phenyl]-1,2-octanedione, 2-(O-benzoyloxime)-1-[4-(methylphenylthio)phenyl]-1,2-butanedione, 2-(O-benzoyloxime)-1-[4-(ethylphenylthio)phenyl]-1,2-butanedione, 2-(O-benzoyloxime)-1-[4-(butylphenylthio)phenyl]-1,2-butanedione, 1-(O-acetyloxime)-1-[9-ethyl-6-(2-methylbenzoyl)-9H-carbazol-3-yl]ethanone, 1-(O-acetyloxime)-1-[9-methyl-6-(2-methylbenzoyl)-9H-carbazol-3-yl]ethanone, 1-(O-acetyloxime)-1-[9-propyl-6-(2-methylbenzoyl)-9H-carbazol-3-yl]ethanone, 1-(O-acetyloxime)-1-[9-ethyl-6-(2-ethylbenzoyl)-9H-carbazol-3-yl]ethanone, 1-(O-acetyloxime)-1-[9-ethyl-6-(2-butylbenzoyl)-9H-carbazol-3-yl]ethanone, 2-(benzoyloxyimino)-1-[4-(phenylthio)phenyl]-1-octanone, 2-(acetoxyimino)-4-(4-chlorophenylthio)-1-[9-ethyl-6-(2-methylbenzoyl)-9H-carbazol-3-yl]-1-butanone, and the like, but the present invention is not limited to these.

In addition, in the present invention, in view of sensitivity, stability over time, and coloring at the time of post-heating, a compound selected from a compound represented by the following formula (1) and a compound represented by the following formula (2) is more preferable as the oxime-based compound.

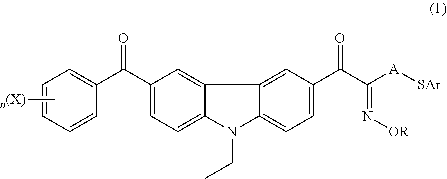

(In formula (1), each of R and X represents a monovalent substituent, A represents a divalent organic group, and Ar represents an aryl group. n represents an integer of 0 to 5.)

In view of a high degree of sensitization, R in formula (1) is preferably an acyl group, and specifically, R is preferably an acetyl group, a propionyl group, a benzoyl group, or a toluoyl group.

In view of increasing sensitivity and inhibiting coloring caused by the passage of time and heating, A is preferably an unsubstituted alkylene group, an alkylene group substituted with an alkyl group (for example, a methyl group, an ethyl group, a tert-butyl group, or a dodecyl group), an alkylene group substituted with an alkenyl group (for example, a vinyl group or an allyl group), or an alkylene group substituted with an aryl group (for example, a phenyl group, a p-tolyl group, a xylyl group, a cumenyl group, a naphthyl group, an anthryl group, a phenanthryl group, or a styryl group).

In view of increasing sensitivity and inhibiting coloring caused by the passage of time and heating, Ar is preferably a substituted or unsubstituted phenyl group. In the case of the substituted phenyl group, as the substituent thereof, for example, halogen atoms such as a fluorine atom, a chlorine atom, a bromine atom, and an iodine atom are preferable.

In view of solvent solubility and improvement of absorption efficiency in a long wavelength region, X is preferably an alkyl group that may have a substituent, an aryl group that may have a substituent, an alkenyl group that may have a substituent, an alkynyl group that may have a substituent, an alkoxy group that may have a substituent, an aryloxy group that may have a substituent, an alkylthioxy group that may have a substituent, an arylthioxy group that may have a substituent, or an amino group that may have a substituent.

Moreover, n in formula (1) is preferably an integer of 0 to 2.

As the compound represented by formula (1), more specifically, a compound having a structure represented by the following (D-2) is preferable.

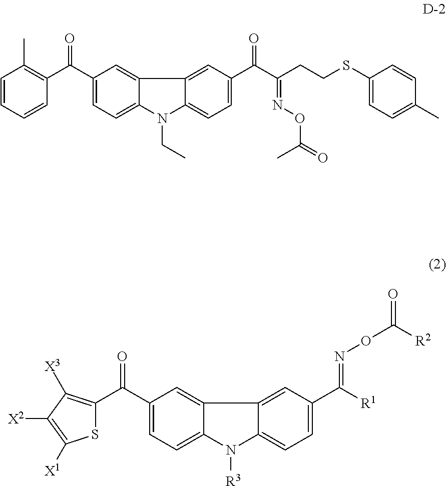

(In formula (2), each of X¹, X², and X³ independently represents a hydrogen atom, a halogen atom, or an alkyl group, R¹ represents —R, —OR, —COR, —SR, —CONRR′, or —CN, and each of R² and R³ independently represents —R, —OR, —COR, —SR, or —NRR′. Each of R and R′ independently represents an alkyl group, an aryl group, an aralkyl group, or a heterocyclic group. These groups may be substituted with one or more substituents selected from a group consisting of a halogen atom and a heterocyclic group, and one or more carbon atoms constituting an alkyl chain in the alkyl group and aralkyl group may be replaced with an unsaturated bond, an ether bond, or an ester bond. R and R′ may form a ring by being bonded to each other.)

As the compound represented by formula (2), more specifically, a compound having a structure represented by the following (D-3) is preferable.

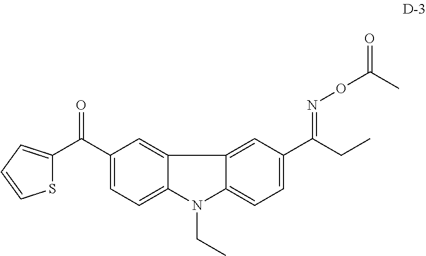 [SMILES: CC/C(=N\OC(C)=O)c1ccc2c(c1)c1cc(C(=O)c3cccs3)ccc1n2CC]

Specific examples of the organic halogenated compound include the compounds described in Wakahayashi et al., “Bull Chem. Soc. Japan”, 42, 2924 (1969), the specification of U.S. Pat. No. 3,905,815, JP-B No. S46-4605, JP-A No. S48-36281, JP-A No. S55-32070, JP-A No. S60-239736, JP-A No. S61-169835, JP-A No. S61-169837, JP-A No. S62-58241, JP-A No. S62-212401, JP-A No. S63-70243, JP-A No. S63-298339, M. P. Hutt “Journal of Heterocyclic Chemistry” 1 (No. 3), (1970), and the like. The examples particularly include an oxazole compound and an s-triazine compound substituted with a trihalomethyl group.

Examples of the hexaarylbiimidazole compound include various compounds described in JP-B No. H06-29285 and each of the specifications of U.S. Pat. No. 3,479,185, U.S. Pat. No. 4,311,783, U.S. Pat. No. 4,622,286, and the like. Specific examples thereof include 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-trifluorophenyl)-4,4′,5,5′-tetraphenylbiimidazole, and the like.

In addition, known photopolymerization initiators described in Paragraph [0079] in JP-A No. 2004-295116 can also be used.

Among these, as the (D) photopolymerization initiator, the above oxime compounds can be preferably used, and particularly, the compounds represented by (D-2) and (D-3) are preferable.

The colored curable composition can contain only one kind of the photopolymerization initiator or two or more kinds thereof in combination.

In view of more markedly obtaining the effects of the present invention, the content (total content when two or more kinds of the photopolymerization initiators are used) of the photopolymerization initiator in a total solid content of the colored curable composition is preferably 0.5% by mass to 30% by mass, more preferably 3% by mass to 20% by mass, even more preferably 4% by mass to 19% by mass, and particularly preferably 5% by mass to 18% by mass.

<Component (E): Other Components>

Hereinafter, additives other than the (D) photopolymerization initiator that may be contained in the colored curable composition of the present invention and preferable as a concurrently used component will be described.

(E-1: Sensitizer)

The colored curable composition of the present invention may contain a sensitizer. Examples of typical sensitizers used in the present invention include those described in J. V. Crivello, “Adv. in Polymer Sci, 62, 1 (1984)”. Specific examples thereof include pyrene, perylene, acridine, thioxanthone, 2-chlorothioxanthone, benzoflavin, N-vinylcarbazole, 9,10-dibutoxyanthracene, anthraquinone, benzophenone, coumarin, ketocoumarin, phenanthrene, camphorquinone, phenothiazine derivatives, and the like. It is preferable that the sensitizer be added in a proportion of 50% by mass to 200% by mass, based on the photopolymerization initiator. The sensitizer increases sensitivity of the coexisting photopolymerization initiator. However, as described above, if an appropriate sensitizer is concurrently used, this brings an advantage that a photopolymerization initiator that is not sensitive directly to the exposure wavelength can also be applied to the colored curable composition of the present invention.

(E-2: Chain Transfer Agent)

The colored curable composition of the present invention may contain a chain transfer agent.

Examples of the chain transfer agent used in the present invention include N,N-dialkylamino benzoic acid alkyl esters such as N,N-dimethylamino benzoic acid ethyl ester, mercapto compounds having a heterocyclic ring, such as 2-mercaptobenzothiazole, 2-mercaptobenzoxazole, 2-mercaptobenzimidazole, N-phenylmercaptobenzimidazole, and 1,3,5-tris(3-mercaptobutyloxyethyl)-1,3,5-triazine-2,4,6(1H,3H,5H)-trione, aliphatic polyfunctional mercapto compounds such as pentaerythritol tetrakis(3-mercaptobutyrate) and 1,4-bis(3-mercaptobutyryloxy)butane, and the like. Among these, aliphatic polyfunctional mercapto compounds are preferable.

One kind of the chain transfer agent may be used alone, or two or more kinds thereof may be used concurrently.

In view of reducing variation of sensitivity, the amount of the chain transfer agent added is preferably within a range of 0.01% by mass to 15% by mass, more preferably 0.1% by mass to 10% by mass, and particularly preferably 0.5% by mass to 5% by mass, based on a total solid content of the colored curable composition of the present invention.

(E-3: Polymerization Inhibitor)

The colored curable composition of the present invention may contain a polymerization inhibitor.

The polymerization inhibitor is a substance that plays a role of deactivating polymerization-initiating species by means of donating (or accepting) hydrogen, donating (or accepting) energy, or donating (or accepting) electrons to the polymerization-initiating species such as a radical generated by light or heat in the colored curable composition so as to inhibit polymerization from being unintentionally initiated. The polymerization inhibitor and the like described in Paragraphs [0154] to [0173] of JP-A No. 2007-334322 can be used.

Among these, preferable examples of the polymerization inhibitor include p-methoxyphenol.

The content of the polymerization inhibitor in the colored curable composition of the present invention is preferably 0.0001% by mass to 5% by mass, more preferably 0.001% by mass to 5% by mass, and particularly preferably 0.001% by mass to 1% by mass, based on a total mass of the polymerizable compound.

(E-4: Organic Solvent)

The colored curable composition of the present invention can contain at least one kind of organic solvent.

Basically, the organic solvent is not particularly limited as long as it can make the solubility of the respective coexisting components and the coating properties of the obtained colored curable composition satisfactory. Particularly, it is preferable that the organic solvent be selected in consideration of the solubility of solid contents such as a binder, coating properties, and safety.

Examples of the organic solvent include esters such as ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, oxyacetic acid alkyl esters (examples: methyl oxyacetate, ethyl oxyacetate, and butyl oxyacetate (specific examples of these include methyl methoxyacetate, ethyl methoxyacetate, butyl methoxyacetate, methyl ethoxyacetate, ethyl ethoxyacetate, and the like)), 3-oxypropionic acid alkyl esters (examples: methyl 3-oxypropionate, ethyl 3-oxypropionate, and the like (specific examples of these include methyl 3-methoxypropionate, ethyl 3-methoxypropionate, methyl 3-ethoxypropionate, ethyl 3-ethoxypropionate, and the like)), 2-oxypropionic acid alkyl esters (examples: methyl 2-oxypropionate, ethyl 2-oxypropionate, propyl 2-oxypropionate, and the like (specific examples of these include methyl 2-methoxypropionate, ethyl 2-methoxypropionate, propyl 2-methoxypropionate, methyl 2-ethoxypropionate, ethyl 2-ethoxypropionate, and the like)), methyl 2-oxy-2-methylpropionate, ethyl 2-oxy-2-methylpropionate (specific examples of these include methyl 2-methoxy-2-methylpropionate, ethyl 2-ethoxy-2-methylpropionate, and the like), methyl pyruvate, ethyl pyruvate, propyl pyruvate, methyl acetoacetate, ethyl acetoacetate, methyl 2-oxobutanoate, ethyl 2-oxobutanoate, and the like.

The examples also include ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate, and the like.

The examples also include ketones such as methyl ethyl ketone, cyclohexanone, 2-heptanone, 3-heptanone, and the like.

The examples also preferably include aromatic hydrocarbons such as toluene, xylene, and the like.

In view of solubility of the above respective components, in view of solubility of an alkali-soluble polymer when the alkali-soluble polymer is contained, and in view of improving the coated surface condition, it is preferable that two or more kinds of the organic solvents be mixed with each other. In this case, a mixed solvent constituted with two or more kinds selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate is particularly preferable.

The content of the organic solvent in the colored curable composition is preferably such an amount that the concentration of a total solid content in the composition becomes 5% by mass to 80% by mass, more preferably such an amount that the concentration becomes 5% by mass to 60% by mass, and particularly preferably such an amount that the concentration becomes 10% by mass to 60% by mass.

(E-5: Crosslinking Agent)

For the colored curable composition of the present invention, a crosslinking agent can be complementarily used to further enhance hardness of a colored cured film that is obtained by curing the colored curable composition.

The crosslinking agent is not particularly limited as long as it enables the film to be cured by a crosslinking reaction. Examples thereof include (a) epoxy resins, (b) melamine compounds, guanamine compounds, glycoluril compounds, or urea compounds substituted with at least one substituent selected from a methylol group, an alkoxymethyl group, and an acyloxymethyl group, (c) phenol compounds, naphthol compounds, or hydroxyanthracene compounds substituted with at least one substituent selected from a methylol group, an alkoxymethyl group, and an acyloxymethyl group. Among these, polyfunctional epoxy resins are preferable.

Regarding details of specific examples and the like of the crosslinking agent, the disclosure of Paragraphs [0134] to [0147] of JP-A No. 2004-295116 can be referred to.

(E-6: Surfactant)

The colored curable composition of the present invention may contain a surfactant.

As the surfactant, any of anionic, cationic, nonionic, and amphoteric surfactants can be used, but nonionic surfactants are preferable.

Examples of the nonionic surfactant include polyoxyethylene higher alkyl ethers, polyoxyethylene higher alkyl phenyl ethers, higher fatty acid diesters of polyoxyethylene glycol, silicone-based surfactants, fluorosurfactants, and the like. Moreover, examples of the surfactant that can be used in the present invention include commercially available surfactants having the following trade names, such as the respective series including KP (manufactured by Shin-Etsu Chemical Co., Ltd.), POLYFLOW (manufactured by KYOEISHA CHEMICAL Co., LTD.), EFTOP (manufactured by JEMCO, INC.), MEGAFACE (manufactured by DIC Corporation), FLUORAD (manufactured by Sumitomo 3M Limited), ASAHI GUARD and SURFLON (manufactured by ASAHI GLASS CO., LTD.), POLYFOX (manufactured by OMNOVA Solutions Inc.).

Moreover, preferable examples of the surfactant include a copolymer that contains repeating units A and B represented by the following formula (1) and has a weight average molecular weight (Mw) expressed in terms of polystyrene of 1,000 to 10,000 which is measured by gel permeation chromatography.

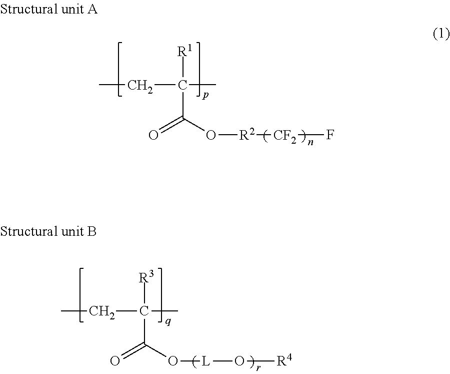

(In Formula (1), each of R¹ and R³ independently represents a hydrogen atom or a methyl group, R² represents a linear alkylene group having 1 to 4 carbon atoms, R⁴ represents a hydrogen atom or an alkyl group having 1 to 4 carbon atoms, L represents an alkylene group having 3 to 6 carbon atoms, p and q represent a mass-based percentage that indicates a polymerization ratio, p represents a numerical value of 10% by mass to 80% by mass, q represents a numerical value of 20% by mass to 90% by mass, r represents an integer of 1 to 18, and n represents an integer of 1 to 10.)

L in the Formula (1) is preferably a branched alkylene group represented by the following Formula (2).

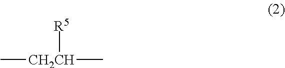

(In Formula (2), R⁵ represents an alkyl group having 1 to 4 carbon atoms. In view of compatibility and wettability for the surface to be coated, R⁵ is preferably an alkyl group having 1 to 3 carbon atoms, and more preferably an alkyl group having 2 to 3 carbon atoms.

The weight average molecular weight (Mw) of the copolymer as the surfactant represented by formula (1) is preferably from 1,500 to 5,000.

One kind of these surfactants can be used alone, or two or more kinds thereof can be used by being mixed with each other.

The amount of the (I) surfactant added to the photosensitive resin composition of the present invention is preferably 10 parts by mass or less, more preferably 0.01 parts by mass to 10 parts by mass, and even more preferably 0.01 parts by mass to 1 part by mass, based on 100 parts by mass of the (A) specific colorant.

(E-7: Adhesion Enhancer)

The colored curable composition of the present invention may contain an adhesion enhancer.

The adhesion enhancer is a compound that enhances adhesion between the cured film and a substrate such as inorganic materials, for example, glass, silicon compounds such as silicon, silicon oxide, and silicon nitride, gold, copper, and aluminum. Specific examples thereof include silane coupling agents, thiol-based compounds, and the like. The silane coupling agent as the adhesion enhancer is for modifying an interface, and known compounds can be used without particular limitation.

As the silane coupling agent, the silane coupling agents described in Paragraph [0048] in JP-A No. 2009-98616 are preferable, and among these, γ-glycidoxypropyl trialkoxysilane and γ-methacryloxypropyl trialkoxysilane are more preferable. One kind of these can be used alone, or two or more kinds thereof can be used concurrently.

In the colored curable composition of the present invention, the content of the adhesion enhancer is preferably 0.1% by mass to 20% by mass and more preferably 0.2% by mass to 5% by mass, based on a total solid content of the colored curable composition.

(E-8: Binder Polymer)

In view of improving film properties and the like, it is preferable that the colored curable composition of the present invention contain a binder polymer.

As the binder polymer, it is preferable to use a linear organic macromolecular polymer. Any type of compound can be used as the “linear organic macromolecular polymer”. However, it is preferable to select a linear organic macromolecular polymer that makes it possible to perform developing by using water or weakly alkaline water and is swellable or soluble in water or weakly alkaline water. The linear organic macromolecular polymer is not only selected and used as an agent for forming a film of the composition, but also selected and used according to the use as a water, weakly alkaline water, or organic solvent developable agent. For example, if a water-soluble organic macromolecular polymer is used, developing can be performed using water. Examples of the above linear organic macromolecular polymer include addition polymers having a carboxylic group on the side chain that are described in, for example, JP-A No. S59-44615, JP-B No. S54-34327, JP-B No. S58-12577, JP-B No. S54-25957, JP-A No. S54-92723, JP-A No. S59-53836, and JP-A No. S59-71048 respectively. That is, examples of such a polymer include methacrylic acid copolymers, acrylic acid copolymers, itaconic acid copolymers, crotonic acid copolymers, maleic acid copolymers, partially esterified maleic acid copolymers, and the like. Moreover, examples of the polymer also include acidic cellulose derivatives having a carboxylic group on the side chain. In addition, a compound and the like obtained by adding a cyclic acid anhydride to an addition polymer having a hydroxyl group are useful.

Among these, a copolymer of [benzyl(meth)acrylate/(meth)acrylic acid/optional other addition-polymerizable vinyl monomers] and a copolymer of [allyl(meth)acrylate/(meth)acrylic acid/optional other addition-polymerizable vinyl monomers] are particularly preferable since these make the film strength, sensitivity, and developability well balanced.

Moreover, as water-soluble linear organic macromolecules other than the above, polyvinyl pyrrolidone, polyethylene oxide, and the like are also useful. Further, in order to enhance the strength of the cured film, alcohol-soluble nylon, polyether of 2,2-bis-(4-hydroxyphenyl)-propane and epichlorohydrin, and the like are also useful. These linear organic macromolecular polymers can be mixed into the entire composition in any amount. In view of the strength and the like of the image to be formed, the amount is preferably 30% by mass to 85% by mass. In addition, a ratio between the polymerizable compound and the linear organic macromolecular polymer is preferably within a range of 1/9 to 7/3 in terms of a mass ratio. In a preferable embodiment, a binder polymer that is practically insoluble in water and is soluble in alkali is used. Accordingly, it is possible not to use an organic solvent that is not preferable in an environmental aspect as a developer, or the amount thereof used can be limited to be extremely small. In this way of use, an acid value (acid content per 1 g of a polymer that is expressed as a chemical equivalent number) and a molecular weight of the binder polymer are appropriately selected in view of the image strength and developability. The acid value is preferably 3 mg KOH/g to 200 mg KOH/g, and the molecular weight is preferably within a range of 3,000 to 100,000 in terms of a mass average molecular weight. The acid value is more preferably 50 mg KOH/g to 150 mg KOH/g, and the molecular weight is more preferably within a range of 10,000 to 50,000.

(E-9: Developing Accelerator)

In order to enhance the alkaline-solubility of a non-exposure region and further improve the developability of the colored curable composition, a developing accelerator can also be added. The developing accelerator is preferably a low-molecular weight organic carboxylic acid compound having a molecular weight of 1,000 or less or a low-molecular weight phenol compound having a molecular weight of 1,000 or less.

Specific examples thereof include aliphatic monocarboxylic acids such as formic acid, acetic acid, propionic acid, butyric acid, valeric acid, pivalic acid, caproic acid, diethylacetic acid, enanthic acid, and caprylic acid; aliphatic dicarboxylic acids such as oxalic acid, malonic acid, succinic acid, glutaric acid, adipic acid, pimelic acid, suberic acid, azelaic acid, sebacic acid, brasylic acid, methylmalonic acid, ethylmalonic acid, dimethylmalonic acid, methylsuccinic acid, tetramethylsuccinic acid, and citraconic acid; aliphatic tricarboxylic acids such as tricarballylic acid, aconitic acid, and camphoronic acid; aromatic monocarboxylic acids such as benzoic acid, toluic acid, cuminic acid, hemellitic acid, and mesitylenic acid; aromatic polycarboxylic acids such as phthalic acid, isophthalic acid, terephthalic acid, trimellitic acid, trimesic acid, mellophanic acid, and pyromellitic acid; phenylacetic acid, hydratropic acid, hydrocinnamic acid, mandelic acid, phenylsuccinic acid, atropic acid, cinnamic acid, methyl cinnamate, benzyl cinnamate, cinnamylidene acetic acid, coumaric acid, umbellic acid, and the like.

(E-10: Other Additives)

In the colored curable composition of the present invention, various other additives such as a filler, a polymer compound other than the above, a UV absorber, an antioxidant, and an aggregation inhibitor can be optionally mixed in. Examples of these additives include those described in Paragraphs [0155] to [0156] of JP-A No. 2004-295116.

The colored curable composition of the present invention can contain the light stabilizer described in Paragraph [0078] of JP-A No. 2004-295116 and the thermal polymerization inhibitor described in Paragraph [0081] of the same gazette.

<Preparation of Colored Curable Composition>

The embodiment for preparing the colored curable composition of the present invention is not particularly limited. However, for example, the (A) specific colorant, (B) another colorant, (C) polymerizable compound, and (D) photopolymerization initiator or various other additives that are concurrently used as desired are mixed with each other to prepare the composition.

Moreover, when the colored curable composition of the present invention is prepared, for the purpose of removing foreign substances, decreasing defectiveness, and the like, it is preferable to mix the respective components together and then filter the mixture through a filter. As the filter, filters that are conventionally used for filtration or the like can be used without particular limitation. Specific examples thereof include filters formed of resin materials selected from fluororesins such as polytetrafluoroethylene (PTFE), polyamide-based resins such as nylon-6 and nylon-6,6, polyolefin resins (optionally with a high density and ultrahigh molecular weight) such as polyethylene and polypropylene (PP), and the like. Among these filter materials, polyamide-based resins such as nylon-6 and nylon-6,6 and polypropylene (including high-density polypropylene) are preferable.

A suitable pore diameter of the filter is about 0.01 μm to 7.0 μm. The pore diameter is preferably about 0.01 μm to 2.5 μm, and more preferably about 0.01 μm to 2.0 μm. If a pore diameter of the filter is within the above range, minute foreign substances that hinder the preparation of a uniform colored curable composition in a post-step are reliably removed, and a colored curable composition that makes it possible to form a uniform and smooth colored curable composition layer is obtained.

In using the filter, different filters may be used in combination. At this time, filtering that is performed using a first filter may be conducted only once or twice or more times. Furthermore, filters having different pore diameters within the range described above may be combined with each other, and plural filters may be used as a first filter to perform first filtering. For the pore diameter mentioned herein, the value officially measured by the filter maker can be referred to. As a commercially available filter, the filter can be selected from various filters supplied from Pall Corporation Japan, ADVANTEC Co., Ltd., Japan Entegris, Inc. (the former Japan Microlis), KITZ MICRO FILTER CORPORATION, and the like.

As a second filter, a filter formed of the same material or the like as that of the first filter described above can be used.

Moreover, for example, the filtering that is performed using the first filter may be conducted only for a pigment dispersion, and second filtering may be performed after other components are mixed with the pigment dispersion to form a colored curable composition.

The colored curable composition of the present invention can be used for various purposes such as a color filter for a solid-state imaging device, a color filter for a liquid crystal display device, printing ink, and ink jet ink.

<Colored Cured Film>

A colored cured film obtained by curing the colored curable composition of the present invention has a high color purity, provides a high degree of absorptivity in a thin layer, and exhibits excellent fastness (particularly, thermal resistance and light fastness). Furthermore, even when a white LED is used as a backlight, if the colored cured film of the present invention is used, a colored pixel having an excellent hue can be formed. Accordingly, the effect of the film becomes marked if it is used for forming colored pixels of a color filter applied to a liquid crystal display device that includes a white LED. Particularly, the colored cured film is suitable for forming a colored pixel in a color filter of a liquid crystal display device.

When the colored cured film is formed on any substrate or any base material, the substrate or the like is coated with or soaked in the colored curable composition to form a colored curable composition layer first, and then the colored curable composition layer may be cured. In addition, when a patterned colored cured film is formed, the colored curable composition may be applied only to a desired region on a substrate by an ink jet recording method, or a known printing method such as textile printing or offset printing may be performed to form a colored curable composition layer only in a desired region. However, in view of making it possible to form a high-definition pattern, a method described later, in which a colored curable composition layer is formed on a substrate and patternwise exposed, and then a non-exposed portion of the colored curable composition layer is removed by developing, is preferable.

<Method for Producing Color Filter>

The method for producing a color filter of the present invention includes a step [hereinafter, also called a “step (i)”] of forming a colored curable composition layer (colored layer) by applying the colored curable composition of the present invention described above onto a substrate, and a step [hereinafter, also called a “step (ii)”] of forming a patterned colored cured film by patternwise exposing the colored curable composition layer (colored layer) and then removing a non-cured portion by means of developing by using a developer.

That is, the colored curable composition of the present invention is applied directly or through another layer onto a substrate such as glass by a method of, for example, spin coating, slit coating, cast coating, roll coating, or ink jet coating, to form a colored layer, and the formed colored layer is exposed to light by a method such as a method of exposing it to light through a predetermined mask pattern [step (i)]. After the exposure, a non-cured portion is removed by means of developing by using a developer to form a colored cured film [step (ii)]. The pattern exposure may be conducted through a mask pattern or by scanning exposure.

The obtained patterned colored cured film is useful as, for example, a pixel of a color filter.

<Color Filter and Method for Producing the Same>

The color filter of the present invention includes a colored cured film formed from the colored curable composition of the present invention on a substrate.

That is, by the method for producing a color filter described below, patterned colored cured films (for example, colored pixels) with the respective colors (for examples, three or four colors) are formed. In this way, it is possible to most preferably prepare a color filter.

Therefore, it is possible to prepare a color filter used for a liquid crystal display device, an organic EL display device, a solid-state imaging device, and the like, with less difficulty in processing and high quality and at a low cost.

In a preferable embodiment, the method for producing a color filter of the present invention further includes at least one step selected from a step [hereinafter, also called a “step (iii)] of irradiating the patterned colored region formed by the step (ii) with UV rays and/or a step [hereinafter, also called a “step (iv)”] of performing heating treatment on the colored region irradiated with UV rays.

Hereinafter, the method for producing a color filter of the present invention will be described in more detail.

—Step (i)—

In the method for producing a color filter of the present invention, first, the colored curable composition of the present invention described above is applied directly or through another layer onto a support by a desired method to form a coating film (colored curable composition layer) formed of the colored curable composition, and then pre-curing (pre-baking) is optionally performed to dry the colored curable composition layer.

Examples of the support include alkali-free glass used for a liquid crystal display device and the like, soda glass, Pyrex (registered trademark) glass, quartz glass, supports obtained by attaching a transparent conductive film to these, photoelectric conversion element substrates used for a solid-state imaging device or the like, for example, a silicon substrate, a plastic substrate, and the like. Moreover, on these supports, a black matrix for isolating the respective pixels from each other may be formed, or a transparent resin layer for facilitating adhesion may be disposed. In addition, if necessary, a basecoat layer may be disposed on the support, for the purpose of improving adhesiveness to the upper layer, preventing diffusion of substances, or planarizing the surface.

Furthermore, it is preferable that a plastic substrate further has at least one layer selected from a gas barrier layer and a solvent-resistant layer on the surface thereof.

In addition, as a support, a driving substrate (hereinafter, also called a “TFT mode liquid crystal driving substrate”) in which a thin film transistor (TFT) of a thin film transistor (TFT) mode color liquid crystal display device is disposed can be used. A colored pattern formed from the colored curable composition of the present invention can also be formed on this driving substrate to prepare a color filter.

Examples of the substrate in the TFT mode liquid crystal driving substrate include glass, silicon, polycarbonate, polyester, aromatic polyamide, polyamide imide, polyimide, and the like. If desired, these substrates can be subjected to appropriate pretreatment in advance such as chemical treatment by using a silane coupling agent and the like, plasma treatment, ion plating, sputtering, a gas-phase reaction method, and vacuum deposition. For example, it is possible to use a substrate obtained by forming a passivation film such as silicon nitride film on the surface of the TFT mode liquid crystal driving substrate.

Examples of the method for applying the colored curable composition of the present invention onto a support include coating methods such as spin coating, slit coating, cast coating, roll coating, bar coating, and ink jetting.

In the step (i), the method for applying the colored curable composition of the present invention onto a support is not particularly limited. However, methods that use a slit nozzle (hereinafter, called a “slit nozzle coating method”) such as a slit-and-spin method and spinless coating method are preferable.

In the slit nozzle coating method, the conditions of the slit-and-spin coating method and the spinless coating method vary in accordance with the size of the substrate to be coated. However, for example, when a fifth generation glass substrate (1,100 mm×1,250 mm) is coated with the colored curable composition by the spinless coating method, the amount of the colored curable composition ejected from the slit nozzle is generally 500 μl/sec to 2,000 μl/sec and preferably 800 μl/sec to 1,500 μl/sec. Moreover, the coating rate is generally 50 mm/sec to 300 mm/sec and preferably 100 mm/sec to 200 mm/sec.

Furthermore, a solid content concentration (solid content concentration in a coating liquid of the colored curable composition) of the colored curable composition used in the step (i) is generally 10% by mass to 20% by mass and preferably 13% by mass to 18% by mass.

In the step (i), pre-baking treatment is performed in general after the colored curable composition layer is formed. If necessary, vacuum treatment may be performed prior to the pre-baking. In the condition of vacuum drying, a degree of vacuum is generally about 13.33 Pa (0.1 torr) to 133.32 Pa (1.0 torr) and preferably about 26.66 Pa (0.2 torr) to 66.66 Pa (0.5 torr).

In addition, the pre-baking treatment can be performed using a hot plate, an oven, and the like, within a temperature range of 50° C. to 140° C. and preferably 70° C. to 110° C., under the condition of 10 seconds to 300 seconds. Moreover, in the pre-baking treatment, high-frequency treatment may be used concurrently with heating treatment. When the colored curable composition layer is dried, it is possible to perform only the high-frequency treatment instead of the pre-baking treatment.

A thickness of the colored curable composition layer formed of the colored curable composition is appropriately selected according to the purpose. For a color filter for a liquid crystal display device, the thickness is preferably within a range of 0.2 μm to 5.0 μm, more preferably within a range of 1.0 μm to 4.0 μm, and most preferably within a range of 1.5 μm to 3.5 μm. Moreover, for a color filter for a solid-state imaging device, the thickness is preferably within a range of 0.2 μm to 5.0 μm, more preferably within a range of 0.3 μm to 2.5 μm, and most preferably within a range of 0.3 μm to 1.5 μm.

In addition, the thickness of the colored curable composition layer is a film thickness after pre-baking

—Step (ii)—

Subsequently, pattern exposure is performed on the coating film (colored curable composition layer) that is formed of the colored curable composition on a support in the manner described above. The pattern exposure is performed through, for example, a photomask.

As light or radiation that can be applied to the exposure, g-line, h-line, i-line, j-line, KrF light, and ArF light are preferable, and particularly, i-line is preferable. When i-line is used as irradiation light, it is preferable that irradiation be performed at an exposure dose of 100 mJ/cm² to 10,000 mJ/cm².

Moreover, as other light sources of exposure, each of ultrahigh pressure, high pressure, medium pressure, and low pressure mercury lamps, a chemical lamp, a carbon arc lamp, a xenon lamp, a metal halide lamp, various laser light sources of visible rays and UV rays, a fluorescent lamp, a tungsten lamp, sunlight, and the like can also be used.

˜Exposure Step that Uses Laser Light Source˜

In the exposure method that uses a laser light source, it is preferable to use an UV light laser as a light source.

As the irradiation light, a UV light laser having a wavelength within a wavelength range of 300 nm to 380 nm is preferable, and a UV light laser having a wavelength within a wavelength range of 300 nm to 360 nm is more preferable, in the respect that the above wavelength matches the photosensitive wavelength of the resist.

Specifically, a third harmonic wave (355 nm) of an Nd:YAG laser as a solid-state laser that has a particularly large output and is relatively inexpensive and excimer lasers such as XeCl (308 nm) and XeF (353 nm) can be preferably used.

The exposure dose for the substance (pattern) to be exposed to light is within a range of 1 mJ/cm² to 100 mJ/cm², and more preferably within a range of 1 mJ/cm² to 50 mJ/cm². If the exposure dose is within the above range, this is preferable in view of productivity for forming a pattern.

The exposure device that can be used in the present invention is not particularly limited. However, as commercially available products, LE5565A (manufactured by Hitachi High-Technologies Corporation.), CALLISTO (manufactured by V-Technology Co., Ltd.), EGIS (manufactured by V-Technology Co., Ltd.), DF2200G (manufactured by Dainippon Screen Mfg Co., Ltd.), and the like can be used, and devices other than the above ones can also be preferably used.

When the production method of the present invention is applied to the production of a color filter for a liquid crystal display device, it is preferable to perform exposure mainly by using h-line or i-line with a proximity exposure machine or a mirror projection exposure machine. Moreover, when a color filter for a solid-state imaging device is produced, it is preferable to mainly use i-line with a stepper exposure machine. Further, when a color filter is produced using a TFT mode liquid crystal driving substrate, as a photomask to be used, a photomask provided not only with a pattern for forming a pixel (colored pattern) but also with a pattern for forming a through hole or a U-shaped dent is used.

In addition, a light emitting diode (LED) and a laser diode (LD) can be used as an active radiation source. Particularly, when a UV source is required, a UV LED and a UV LD can be used. For example, NICHIA CORPORATION has marketed a violet LED of which a main emission spectrum has wavelengths between 365 nm to 420 nm. Regarding a case in which a shorter wavelength is required, an LED that can emit active radiation centered between 300 nm and 370 nm is disclosed in the specification of U.S. Pat. No. 6,084,250. Moreover, other UV LEDs are also available, and radiations of different UV bands can be irradiated. In the present invention, a UV-LED is particularly preferable as an active radiation source. Particularly, a UV-LED having a peak wavelength in a range of 340 nm to 370 nm is preferable.

Since the UV light laser has excellent parallelism, pattern exposure can be performed even if a mask is not used for the exposure. However, when pattern exposure is performed using a mask, this is more preferable since linearity of the pattern becomes better.

The colored curable composition layer exposed to light as described above can be heated.

Moreover, in order to inhibit the oxidation and discoloration of coloring materials in the colored curable composition layer, exposure can be performed in a chamber under a nitrogen gas flow.

Thereafter, the colored curable composition layer having been exposed to light is developed by a developer, and as a result, a negative or positive colored pattern (resist pattern) can be formed. During the developing, a non-cured portion after exposure is eluted by the developer to leave only a cured portion on the substrate.

Any type of developer can be used as long as it dissolves the coating film (colored curable composition layer) of the colored curable composition in the non-cured portion and does not dissolve the cured portion. For example, a combination of various organic solvents or an aqueous alkaline solution can be used.

Examples of the organic solvent used for developing include the solvents described above that can be used for preparing the colored curable composition of the present invention.

Examples of the above aqueous alkaline solution include aqueous alkaline solutions in which alkaline compounds such as sodium hydroxide, potassium hydroxide, sodium carbonate, sodium hydrogen carbonate, sodium silicate, sodium metasilicate, aqueous ammonia, ethylamine, diethylamine, dimethylethanolamine, tetramethyl ammonium hydroxide, tetraethyl ammonium hydroxide, choline, pyrrole, piperidine, and 1,8-diazabicyclo-[5,4,0]-7-undecene have been dissolved at a concentration of 0.001% by mass to 10% by mass and preferably at a concentration of 0.01% by mass to 1% by mass.

When the developer is the aqueous alkaline solution, the alkali concentration is preferably adjusted to be pH 11 to pH 13, and more preferably adjusted to be pH 11.5 to pH 12.5.

To the aqueous alkaline solution, for example, a water-soluble organic solvent such as methanol or ethanol, a surfactant, and the like can also be added in an appropriate amount.

Regarding the developing temperature, it is preferable to conduct developing by using a developer of which the temperature is generally within a range of 20° C. to 30° C., and the developing time is preferably 20 seconds to 90 seconds.

During the developing, the developer may be used in any methods including a dipping method, a shower method, and a spraying method. In addition, these methods may be combined with a method such as a swing method, a spin method, or an ultrasonic method that adds a certain stress in a developer bath. It is also possible to use a method that prevents development irregularity by dampening in advance the surface to be developed by using water or the like before the surface comes into contact with the developer. Furthermore, the substrate having the colored curable composition layer having been exposed to light can be tilted when performing the developing treatment.

Moreover, for producing a color filter for a solid-state imaging device, paddle development by which the developing treatment is performed while the inside of the developer bath is being stirred may be used.

After the developing treatment, rinsing treatment for washing and removing the surplus developer is performed, the resultant is dried, and then heating treatment (post-baking) is performed to completely cure the resultant.

The rinsing treatment is generally performed using pure water. However, in order to save water, a method of using pure water for final washing and reusing the used pure water for initial washing, a method of washing the substrate by tilting it, or a method of concurrently using ultrasonic irradiation may be used.

In general, after the rinsing treatment, the substrate is drained and dried, and then heating treatment is performed at about 150° C. to 250° C. in the manner described in detail below. In this heating treatment (post-baking: step (iv)), the coating film after developing can be treated by a continuous process or batch process by using heating means such as a hot plate, a convection oven (hot air circulation dryer), and a high-frequency heater, under the conditions described above.

If the above respective steps are sequentially repeated for the respective colors according to the number of the desired hues, a color filter in which a cured film (colored pattern) colored with plural colors is formed can be prepared.

—Step (iii)—

In the method for producing a color filter of the present invention, post-exposure by performing UV irradiation particularly on the patterned colored region (colored pixel) formed from the colored curable composition can be conducted.

—Step (iv)—

It is preferable that heating treatment be further performed on the patterned colored region that has undergone the post-exposure by means of UV irradiation as described above. If the heating treatment (so-called post baking treatment) is performed on the formed colored region, the colored region can be further cured. The heating treatment can be performed using, for example, a hot plate, various heaters, and an oven.

The temperature of the heating treatment is preferably 100° C. to 300° C., and more preferably 150° C. to 250° C. Moreover, the heating time is preferably about 10 minutes to 120 minutes.

The patterned colored region (colored cured film) obtained in this manner constitutes a pixel in a color filter. For preparing a color filter having pixels of plural hues, the above steps (i) and (ii) and optionally the step (iii) or (iv) may be repeated according to the desired number of colors.

In addition, whenever formation, exposure, and development of a colored curable composition layer of a single color end (for every single color), at least one step selected from the steps (iii) and (iv) may be performed. Alternatively, after the formation, exposure, and developing of all of the colored curable composition layers having a desired number of colors end, at least one step selected from the steps (iii) and (iv) may be performed in a batch manner.

In the colored cured film obtained by the method for producing a color filter of the present invention, or the color filter (color filter of the present invention) including the colored cured film formed from the colored curable composition of the present invention, the colored curable composition of the present invention is used. Accordingly, when an image is displayed, the color is vivid, contrast is high, and fastness (particularly, thermal resistance and light fastness) thereof is excellent. Moreover, as described later, a marked effect that makes it possible to reproduce an excellent hue is exerted, not only when the known CCFL is used as a backlight, but also when a white LED is used as a backlight.

The color filter of the present invention can be used for liquid crystal display devices or solid-state imaging devices, and is particularly preferable for liquid crystal display devices. When the color filter is used for liquid crystal display devices, an excellent hue is achieved using a dye as a colorant, and an image excellent in spectral characteristics and contrast can be displayed. Furthermore, the color filter is excellently suitable for a white LED.

So far, the use of the colored curable composition of the present invention has been described mainly by being focused on the use for forming a colored pattern of a color filter. However, the composition can also be used for forming a black matrix that isolates colored patterns (pixels) constituting a color filter from each other.

A black matrix on a substrate can be formed in a manner in which a colored curable composition that contains a light-blocking pigment as a black pigment such as carbon black or titanium black is used, this composition undergoes the respective steps including coating, exposure, and developing, and then post-baking is optionally performed.

When the colored curable composition of the present invention is applied onto a substrate to form a colored layer, a thickness of the dried colored layer is generally 0.3 μm to 5.0 μm, preferably 0.5 μm to 3.5 μm, and most preferably 1.0 μm to 2.5 μm.

<Display Device (Liquid Crystal Display Device and Organic EL Display Device)>

The color filter of the present invention is particularly preferable as a color filter for display devices such as liquid crystal display devices and organic EL display devices. The liquid crystal display devices and organic EL display devices including such a color filter can display a high-quality image.

The definition of the display device and details of the respective display devices are described, for example, in “Electronic Display Devices (Akio, SASAKI, Kogyo Chosakai Publishing Co., Ltd., 1990)”, “Display Devices (Toshiyuki, IBUKI, Sangyo Tosho Publishing Co., Ltd., 1989), and the like. Moreover, liquid crystal display devices are described, for example, in “Next Generation Liquid Crystal Display Technology (edited by Tatsuo UCHIDA, Kogyo Chosakai Publishing Co., Ltd., 1994). The liquid crystal display devices to which the present invention can be applied are not particularly limited, and for example, the present invention can be applied to the liquid crystal display devices of various modes that are described in the above “Next Generation Liquid Crystal Display Technology”.

The color filter of the present invention markedly exerts its effect particularly when being used in color TFT mode liquid crystal display devices among the above devices. The color TFT mode liquid crystal display devices are described, for example, in “Color TFT Liquid Crystal Display (KYORITSU SHUPPAN CO., LTD, 1996). The color filter of the present invention can also be applied to the liquid crystal display devices having a widened viewing angle that employ a lateral electric field driving mode such as IPS or a pixel division mode such as MVA, and STN, TN, VA, OCS, FFS, R-OCB, and the like.

The color filter of the present invention can also be used in a bright and high-definition Color-filter On Array (COA) mode. In a COA mode liquid crystal display device, a color filter layer is required to satisfy general required characteristics described above and also satisfy required characteristics regarding an interlayer dielectric film, that is, a low dielectric constant and remover resistance. The color filter of the present invention is considered to improve the permeability of a UV light laser as light for exposure, by means of selecting the hue or film thickness of the pixel specified by the present invention in addition to the exposure method using the UV light laser. As a result, curability of the colored pixel is improved, and pixels free of cracks, peeling, and twist can be formed. Consequently, remover resistance of a colored layer that is directly or indirectly disposed on a TFT substrate is particularly improved, so the color filter of the present invention is useful for a COA mode liquid crystal display device. In order to further improve the required characteristic of a low dielectric constant, a resin film may be further disposed on the color filter layer.

In a colored layer formed by the COA mode, in order to cause conduction between ITO electrodes arranged on the colored layer and a terminal of a driving substrate under the colored layer, a conduction path such as a rectangular through hole of which the length of one side is about 1 μm to 15 μm or a U-shaped dent needs to be formed. It is particularly preferable to set the size (that is, length of one side) of the conduction path to be 5 μm or less. However, if the color filter of the present invention that includes a colored layer having excellent curability is used, a conduction path equal to or smaller than 5 μm can be easily formed.

The image display modes described above are described in, for example, “EL, PDP, and LCD Display Technology and Recent Trends of the Market (TORAY RESEARCH CENTER, research and study department, 2001), p. 43, and the like.

The liquid crystal display device and the organic EL display device of the present invention are constituted with various members such as an electrode substrate, a polarizing film, a phase difference film, a backlight, a spacer, and a viewing angle compensation film, in addition to the color filter of the present invention. The color filter of the present invention can be applied to liquid crystal display devices and organic EL display devices that are constituted with the above known members.

These members are described, for example, in “'94 Market for Liquid Crystal Display Related Materials and Chemicals (Kentaro, SHIMA, CMC Publishing CO., LTD., 1994)” and “2003 Current Situation of Liquid Crystal-Related Market and Future Prospects (2^{nd} volume) (Yoshikichi HYO, Fuji Chimera Research Institute, Inc., 2003)”.

The backlight is described in SID meeting Digest 1380 (2005) (A. Konno et al.), Display (monthly publication), December, 2005, pp 18-24 (Yasuhiro, SHIMA) and pp 25-30 (Takaaki HACHIKI), and the like.

If the color filter of the present invention is used for a liquid crystal display device, when the color filter is combined with a three-wavelength tube of a cold cathode tube as a backlight or an LED light source of red, green, and blue (RGB-LED), a high contrast can be realized. When an LED light source having an emission spectrum at wavelengths of around 450 nm and 550 nm is used as backlight, a particularly excellent hue is obtained from the color filter having colored pixels obtained using the colored curable composition of the present invention, and a high degree of color reproducibility is obtained.

Particularly preferable examples of the backlight include LED light sources having a peak wavelength of light emission intensity within a range of 430 nm to 470 nm.

That is, a liquid crystal display device including the color filter that has color pixels obtained using the colored curable composition of the present invention and the LED backlight that has a peak wavelength of light emission intensity within a range of 430 nm to 470 nm becomes a liquid crystal display device that can provide a particularly excellent image.

Moreover, an organic EL display device including the color filter that has colored pixels obtained using the colored curable composition of the present invention and a phosphor that has a peak wavelength of light emission intensity within a range of 430 nm to 470 nm becomes a display device that can provide an image having high luminance and excellent color reproducibility.

Examples of the LED backlight that has a peak wavelength of light emission intensity within a range of 430 nm to 470 nm include a Y phosphor:YAG-based phosphor, a TAG-based phosphor, an α-sialon phosphor, a G phosphor:β-sialon phosphor, a silicate-based phosphor, a BSS phosphor, a BSON phosphor, an R phosphor:CASN phosphor, an SCASN phosphor, and the like, and any of these can be applied to the display device of the present invention.

### EXAMPLES

### Examples 1 to 7, and Comparative Examples 1 and 2

—Preparation of Colored Curable Composition—

The respective components shown below were compounded in the amounts shown in the following Table 1 and mixed for 10 minutes at room temperature (25° C.). Thereafter, the mixture was left to stand for 10 minutes and filtered through HDC II (manufactured by Pall Corporation Japan) to obtain a colored curable composition. The numerical values described in Table 1 indicate the content (% by mass) of the respective components, and the symbol “-” indicates that the composition does not contain the component.

(Component)

(A1) A colorant represented by the following Formula 1 [component (A)]

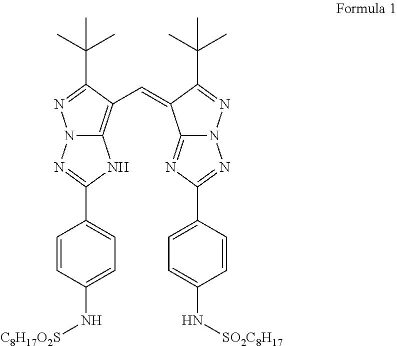

The concentration of a solution containing the colorant represented by the Formula 1 was adjusted to yield an absorbance of 0.8 to 1.0 by using PGMEA. A maximum absorption peak wavelength thereof measured using a CARY 5/UV-visible spectrophotometer (commercially available product: manufactured by Varian Medical Systems, Inc.) was 450 nm.

(B1) A pigment dispersion obtained by mixing 14.9 parts of C. I. Pigment Green 58 and 7.1 parts of an acryl-based pigment dispersant [a methyl methacrylate/methacrylic acid (80/20) [mass ratio] copolymer (weight average molecular weight: 12,000)] with 78.0 parts of propylene glycol monomethyl ether acetate, and sufficiently dispersing the pigment by using a bead mill [component (B)]

The pigment dispersion of C. I. Pigment Green 58 obtained as above was further diluted with propylene glycol monomethyl ether acetate (hereinafter, described as “PGMEA”), and the concentration thereof was adjusted to yield an absorbance of 0.8 to 1.0. A maximum absorption peak wavelength thereof measured using a CARY 5/UV-visible spectrophotometer (commercially available product: manufactured by Varian Medical Systems, Inc.) was 661 nm.

(B2) A pigment dispersion obtained by mixing 12.8 g of C. I. Pigment Yellow 150 and 7.2 parts of an acryl-based pigment dispersant [a methyl methacrylate/methacrylic acid (80/20) [mass ratio] copolymer (weight average molecular weight: 12,000)] with 80.0 parts of propylene glycol monomethyl ether acetate, and sufficiently dispersing the pigment by using a bead mil [component (B)]

(C1) A photopolymerizable compound: KAYARAD DPHA (manufactured by NIPPON KAYAKU Co., Ltd.) [component (C)]

(D1) A photopolymerization initiator: 2-(benzoyloxyimino)-1-[4′-(phenylthio)phenyl]-1-octanone (manufactured by BASF; IRGACURE OXE 01) [component (D)]

(D2) A photopolymerization initiator: the following compound

(D3) A photopolymerization initiator: the following compound

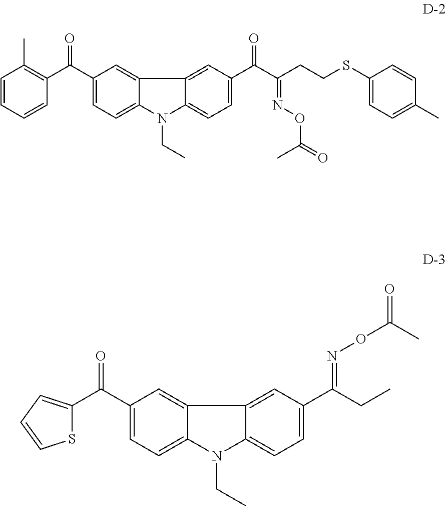 [SMILES: CCn1c2ccc(C(=O)/C(CCSc3ccc(C)cc3)=N/OC(C)=O)cc2c2cc(C(=O)c3ccccc3C)ccc21 ; CC/C(=N\OC(C)=O)c1ccc2c(c1)c1cc(C(=O)c3cccs3)ccc1n2CC]

(D4) A photopolymerization initiator: IRGACURE 369 (manufactured by BASF: a acyl amino-based compound)

(E1) Propylene glycol monomethyl ether acetate [solvent]

(E2) Ethyl 3-ethoxypropionate [solvent]

(E3) Pentaerythritol tetrakis(3-mercaptobutyrate) [polyfunctional mercapto compound]

(F1) Binder resin: allyl methacrylate/methacrylic acid (80:20 (molar ratio))

(G1) 4-Methoxyphenol

(H1) Surfactant: MEGAFACE F781-F (manufactured by DIC Corporation)

TABLE 1

| | | Comparative | | Comparative | | | | | |
|---|---|---|---|---|---|---|---|---|---|
| Component | Example 1 | Example 1 | Example 2 | Example 2 | Example 3 | Example 4 | Example 5 | Example 6 | Example 7 |
| A1 | 1.74 | — | 4.88 | — | 2.01 | 1.74 | 1.74 | 1.74 | 1.74 |
| B1 | 31.01 | 31.95 | 22.76 | 23.98 | 23.43 | 31.01 | 31.01 | 31.01 | 31.01 |
| B2 | — | 6.96 | — | 15.99 | 9.06 | — | — | — | — |
| C1 | 4.18 | 4.41 | 3.35 | 4.34 | 3.95 | 4.18 | 4.18 | 4.18 | 3.67 |
| D1 | 1.04 | 1.09 | 0.83 | 1.08 | 0.98 | — | — | — | — |
| D2 | — | — | — | — | — | 1.04 | — | — | 1.04 |
| D3 | — | — | — | — | — | — | 1.04 | — | — |
| D4 | — | — | — | — | — | — | — | 1.04 | — |
| E1 | 34.61 | 28.61 | 41.05 | 27.99 | 33.67 | 34.61 | 34.61 | 34.61 | 34.61 |
| E2 | 25.2 | 25.2 | 25.2 | 25.2 | 25.2 | 25.2 | 25.2 | 25.2 | 25.2 |
| E3 | — | — | — | — | — | — | — | — | 0.51 |
| F1 | 2.19 | 1.74 | 1.91 | 1.39 | 1.66 | 2.19 | 2.19 | 2.19 | 2.19 |
| G1 | 0.0021 | 0.0022 | 0.0017 | 0.0022 | 0.002 | 0.0021 | 0.0021 | 0.0021 | 0.0021 |
| H1 | 0.032 | 0.032 | 0.032 | 0.032 | 0.032 | 0.032 | 0.032 | 0.032 | 0.032 |
| Total | 100 | 100 | 100 | 100 | 100 | 100 | 100 | 100 | 100 |

—Evaluation of Colored Curable Composition—

1. Formation of Colored Cured Film

The colored curable composition of Example 1 obtained as above was coated onto glass [manufactured by Corning Incorporated; EAGLE-XG (trade name: thickness of 0.7 mm)] by spin coating, and then volatile components were volatilized for 2 minutes at 80° C., thereby forming a coating film 1.

After being cooled, the coating film 1 was exposed to light by being irradiated with i-line [wavelength of 365 nm]. As a light source of the i-line, an ultrahigh pressure mercury lamp was used, and the irradiation was performed using parallel light. The irradiation dose was 50 mJ/cm². Thereafter, post-baking was performed for 20 minutes at 230° C., thereby obtaining a colored cured film 1 having a film thickness of 2 μm. Moreover, the respective colored curable compositions of Examples 2 and 3, Comparative Examples 1 and 2, and Examples 4 to 7 were also formed into coating films and exposed to light in the same manner as above, thereby preparing colored cured films 2 to 9.

That is, colored cured films 2 and 3 were prepared from the colored curable compositions of Examples 2 and 3, colored cured films 4 and 5 were prepared from the colored curable compositions of Comparative Examples 1 and 2, and colored cured films 6 to 9 were prepared from the colored curable compositions of Examples 4 to 7 respectively.

2. Chromaticity Evaluation

Each of the colored cured films 1 to 9 obtained as above was evaluated in the following manner.

As light sources, an LED backlight (LS-XL2370KF, manufactured by Samsung Electronics Co., Ltd.) and a CCFL backlight (product employed in LC-32 GH5, manufactured by SHARP CORPORATION) were used, and the brightness that was measured using a microscopic spectrophotometer OSP-SP200 (manufactured by OLYMPUS CORPORATION) while adjusting the values of x and y to target values was evaluated based on a value of Y. The values of x=0.30 and y=0.60 indicate the chromaticity of green for the HDTV standard. When the values of x and y are as above, the higher the value of Y is, the better the performance of liquid crystal display is.

3. Contrast and Luminance Evaluation

The obtained colored cured film was interposed between two sheets of polarizing film. Values of the luminance obtained when polarizing axes of the two sheets of polarizing film were parallel and when they were orthogonal were measured using a luminance colorimeter (manufactured by TOPCON TECHNOHOUSE CORPORATION, model number: BM-5A). The value of luminance obtained when the polarizing axes of two sheets of polarizing film were parallel was divided by the value of the luminance obtained when the axes were orthogonal, and the thus obtained value was determined as contrast (described as “CR” in Tables 2 to 4). The higher the numerical values described in the column of contrast (CR), the better the performance as a color filter for liquid crystal display.

4. Thermal Resistance Measurement

The sample used for measuring contrast as above was subjected to forced heating treatment for 1 hour in an oven at 230° C. The color difference before and after heating was measured and used as an index of thermal resistance. Moreover, chromaticity was measured using a microscopic spectrophotometer (manufactured by OLYMPUS CORPORATION; OSP100 or 200), calculated as a result of 2° field of view of F10 light source, and expressed as an xyY value of an xyz color system. Furthermore, a difference of the chromaticity is indicated by the color difference of an La*b* color system. The smaller the color difference, the higher the thermal resistance.

5. Patterning Suitability Evaluation

The above colored curable composition was exposed to light by being irradiated with i-line [wavelength of 365 nm] through a mask in which a pattern with a line width of 20 μm was formed, under the same conditions as described above. Thereafter, the resultant was developed using a developer (an aqueous solution containing sodium carbonate/sodium hydrogen carbonate (concentration of 2.4%)) and washed with water. Subsequently, the fine lines of the formed patterned colored cured film were observed with an optical microscope at a 200× magnification to evaluate whether or not the pattern had been formed according to the designed value, based on the following criteria. If the composition was ranked C, it meant that the composition was at a level practically problematic for being used as a color filter resist.

AA: line width of 19 μm or greater
A: line width of 17 μm or greater but less than 19 μm
B: line width of 15 μm or greater but less than 17 μm
C: line width of less than 15 μm

TABLE 2

| | | Relative | | | | | | | | | Thermal |
|---|---|---|---|---|---|---|---|---|---|---|---|
| | Colorant | fluorescence | LS-XL2370KF (SEC; LED) | | | | LC-32GH5 (SC; CCFL) | | | Patterning | resistance |
| | concentration | intensity | x | y | Y | CR | x | y | Y | suitability | ΔEab |
| Example 1 | 40% | 1.2 | 0.3 | 0.6 | 61.3 | 23000 | 0.271 | 0.576 | 60.9 | AA | 2.1 |
| Comparative | 36% | 0.5 | 0.3 | 0.6 | 59.7 | 22500 | 0.272 | 0.578 | 59.3 | A | 2.3 |
| Example 1 | | | | | | | | | | | |
| Example 2 | 52% | 1.1 | 0.327 | 0.614 | 65.9 | 22000 | 0.3 | 0.6 | 64.7 | AA | 2.2 |
| Comparative | 37% | 0.5 | 0.327 | 0.612 | 62.7 | 23500 | 0.3 | 0.6 | 61.5 | A | 2.1 |
| Example 2 | | | | | | | | | | | |
| Example 3 | 43% | 1.1 | 0.327 | 0.613 | 94.1 | 23000 | 0.3 | 0.6 | 62.9 | AA | 2.2 |
| Example 4 | 40% | 1.2 | 0.3 | 0.6 | 61.7 | 23000 | 0.271 | 0.576 | 60.9 | AA | 2.1 |
| Example 5 | 40% | 1.1 | 0.3 | 0.6 | 61.6 | 23000 | 0.271 | 0.576 | 61 | AA | 2.1 |
| Example 6 | 40% | 1.1 | 0.3 | 0.6 | 61.9 | 23000 | 0.271 | 0.576 | 61 | B | 2.1 |
| Example 7 | 40% | 0.9 | 0.3 | 0.6 | 61.9 | 23500 | 0.271 | 0.576 | 61.1 | AA | 2.1 |

As clearly shown in Table 2, all of the colored cured films 1 to 3 and colored cured films 6 to 9 obtained from the colored curable compositions of Examples 1 to 7 of the present invention exhibit G chromaticity of the HDTV standard when being combined with a CCFL backlight, and the luminance at that time is high, and contrast and patterning suitability are excellent. Among these, Example 1 exhibits G chromaticity of the HDTV standard when being combined with an LED backlight, and the patterning suitability thereof is particularly excellent. Presumably, this is because the concentration of the colorant that is required for achieving excellent luminance and hue is suppressed to be low.

On the other hand, though the colored cured film 4 obtained from the colored curable composition of Comparative Example 1 in which the (A) specific colorant according to the present invention is not used but the known yellow colorant (B2) is used exhibits G chromaticity of the HDTV standard when being combined with an LED backlight, the luminance at that time is low. Moreover, though the colored cured film 5 obtained from the colored curable composition of Comparative Example 2 exhibits G chromaticity of the HDTV standard when being combined with a CCFL backlight, luminance at that time is low. Accordingly, it is understood that the performance of both the films as a color pixel of a color filter is insufficient.

In addition, it is understood that if the (A) specific colorant according to the present invention is used concurrently with an oxime compound as the (D) photopolymerization initiator, patterning suitability becomes better. It is also understood that if a polyfunctional mercapto compound is concurrently used, patterning suitability becomes better, and contrast or luminance is further improved.

Furthermore, on the whole, it is understood that the thermal resistance of the color filter formed from the colored curable composition of the present invention is high, and a ΔEab value thereof is low.

### Examples 8 to 10

Colored curable compositions of Examples 8 to 10 were obtained respectively in the same manner as in Examples 1 to 3 and evaluated in the same manner as above, except that the (A) specific colorant used in the Examples 1 to 3 was replaced with a compound represented by the following Formula 2. The results are shown in the following Table 3.

A maximum peak wavelength of the compound represented by the following Formula 2 was measured in the same manner as the compound represented by the Formula 1, and as a result, it was 460 nm.

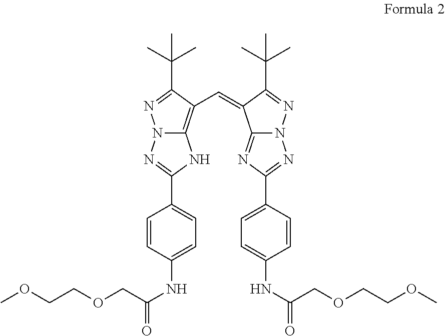

TABLE 3

| | | Relative | | | | | | | | | Thermal |
|---|---|---|---|---|---|---|---|---|---|---|---|
| | Colorant | fluorescence | LS-XL2370KF (SEC; LED) | | | | LC-32GH5 (SC; CCFL) | | | Patterning | resistance |
| | concentration | intensity | x | y | Y | CR | x | y | Y | suitability | ΔEab |
| Example 8 | 39% | 1.2 | 0.3 | 0.6 | 61.3 | 23000 | 0.271 | 0.576 | 60.8 | A | 2.7 |
| Example 9 | 50% | 1.1 | 0.327 | 0.614 | 65.9 | 21500 | 0.3 | 0.6 | 64.8 | B | 2.8 |
| Example 10 | 41% | 1.1 | 0.327 | 0.613 | 64 | 22500 | 0.3 | 0.6 | 62.9 | A | 2.7 |

As clearly shown in Table 3, all of the colored cured films in which the colored curable compositions of Examples 8 to 10 are used exhibit G chromaticity of the HDTV standard when being combined with a CCFL backlight. The luminance at that time is high, the contrast is excellent, and the patterning suitability is at a level unproblematic for practical use. Moreover, from the comparison between Examples 1 to 3 and Examples 8 to 10, it is understood that when the (A) specific colorant excellent in solubility that is represented by the Formula 1 is used, the patterning suitability and thermal resistance are better, compared to a case of using the (A) specific colorant represented by the Formula 2.

### Comparative Examples 4 to 8

Colored curable compositions were respectively obtained and evaluated in the same manner as in Examples 1 to 3 and Comparative Examples 1 and 2, except that the following colorant (solvent yellow 162: SY-162) was used instead of the (A) specific colorant or the comparative colorant (B2) used in the Examples 1 to 3 and Comparative Examples 1 and 2. The results are shown in the following Table 4. A maximum peak wavelength of the solvent yellow 162 was measured in the same manner as the compound represented by the Formula 1, and as a result, it was 425 nm.

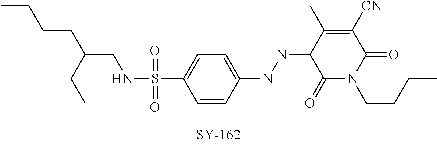 [SMILES: CCCCC(CC)CNS(=O)(=O)c1ccc(NNC2C(=O)N(CCCC)C(=O)C(C#N)=C2C)cc1]

TABLE 4

| | | Relative | | | | | | | | | Thermal |
|---|---|---|---|---|---|---|---|---|---|---|---|
| | Colorant | fluorescence | LS-XL2370KF (SEC; LED) | | | | LC-32GH5 (SC; CCFL) | | | Patterning | resistance |
| | concentration | intensity | x | y | Y | CR | x | y | Y | suitability | ΔEab |
| Comparative | 33% | 1.0 | 0.3 | 0.6 | 60.4 | 23500 | 0.271 | 0.576 | 58.9 | A | 5.5 |
| Example 3 | | | | | | | | | | | |
| Comparative | 36% | 0.5 | 0.3 | 0.6 | 59.7 | 22500 | 0.272 | 0.578 | 59.3 | A | 2.3 |
| Example 4 | | | | | | | | | | | |
| Comparative | 44% | 0.8 | 0.327 | 0.614 | 63.6 | 22000 | 0.3 | 0.6 | 62.3 | A | 6.3 |
| Example 5 | | | | | | | | | | | |
| Comparative | 37% | 0.5 | 0.327 | 0.612 | 62.7 | 23500 | 0.3 | 0.6 | 61.5 | A | 2.1 |
| Example 6 | | | | | | | | | | | |
| Comparative | 35% | 0.9 | 0.327 | 0.613 | 62.4 | 22000 | 0.3 | 0.6 | 61.3 | A | 5.9 |
| Example 7 | | | | | | | | | | | |

As clearly shown in Table 4, when the solvent yellow 162 is used as a yellow colorant, due to a low fluorescence intensity, a high solubility, and a high color value resulting from the characteristics of the colorant, a high contrast is realized while the concentration of the coloring material is suppressed to be low, and the patterning suitability is excellent. When the shapes of absorption curves are observed, the maximum absorption wavelengths and peak heights are almost the same. However, while the (A) specific colorant according to the present invention exhibits a sharp absorption curve with the maximum absorption as the center, the solvent yellow 162 is confirmed to absorb light to some extent even in a wavelength region distant from the maximum absorption region of the absorption curve, and a high degree of absorption is observed particularly at both ends. Accordingly, the solvent yellow 162 has a characteristic that the luminance (Y value) thereof is lower than that of the (A) specific colorant according to the present invention. It is also understood that this colorant tends to have a low degree of thermal resistance and a large ΔEab value.

When a pigment dispersion of Pigment Yellow 150, Pigment Yellow 138, or the like is used instead of the solvent yellow 162 so as to improve thermal resistance, the luminance tends to be further reduced. From these facts, it has been confirmed that the color filter in which the (A) specific colorant according to the present invention is used as a yellow colorant has superior characteristics that a higher contrast and higher luminance are realized and thermal resistance is better, compared to the case of using other yellow dyes or yellow pigments as a colorant.

All publications, patent applications, and technical standards mentioned in this specification are herein incorporated by reference to the same extent as if each individual publication, patent application, or technical standard was specifically and individually indicated to be incorporated by reference.

What is claimed is:

1. A colored curable composition for a color filter, comprising:
(A) at least one colorant selected from the group consisting of a compound represented by the following formula (I) and a compound represented by the following formula (II): 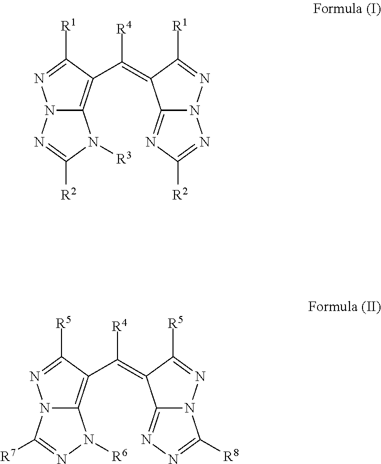
wherein, in formula (I), each of R¹, R², R³, and R⁴ independently represents a hydrogen atom, an alkyl group, an alkoxy group, an alkoxycarbonyl group, a carbamoyl group, a sulfamoyl group, a cyano group, an aryl group, or a heteroaryl group; plural R¹s present in a molecule may be the same as or different from each other; and plural R²s present in the molecule may be the same as or different from each other; and wherein, in formula (II), each of R⁴, R⁵, R⁶, R⁷, and R⁸ independently represents a hydrogen atom, an alkyl group, an alkoxy group, an alkoxycarbonyl group, a carbamoyl group, a sulfamoyl group, a sulfonylamino group, a carbonylamino group, a cyano group, an aryl group, or a heteroaryl group; and plural R⁵s present in a molecule may be the same as or different from each other;
(B) a zinc phthalocyanine compound represented by the following formula (III): 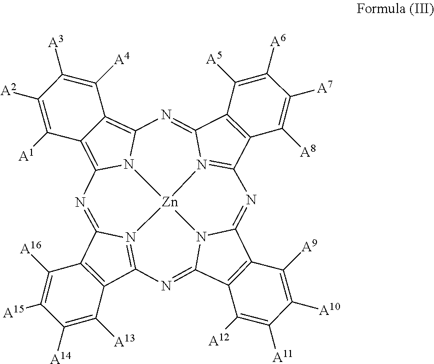
wherein, in formula (III), each of A¹, A², A³, A⁴, A⁵, A⁶, A⁷, A⁸, A⁹, A¹⁰, A¹¹, A¹², A¹³, A¹⁴, A¹⁵, and A¹⁶ independently represents a hydrogen atom, a halogen atom, an alkyl group, an alkoxy group, or a thioalkoxy group; and at least one of A¹, A², A³, A⁴, A⁵, A⁶, A⁷, A⁸, A⁹, A¹⁰, A¹¹, A¹², A¹³, A¹⁴, A¹⁵, or A¹⁶ represents a halogen atom; and
(C) a polymerizable compound.

2. The colored curable composition for a color filter according to claim 1, wherein a maximum absorption peak wavelength of the (B) zinc phthalocyanine compound in a wavelength region of from 380 nm to 800 nm is within a range of from 500 nm to 800 nm.

3. The colored curable composition for a color filter according to claim 1, further comprising (D) a photopolymerization initiator.

4. The colored curable composition for a color filter according to claim 3, wherein the (D) photopolymerization initiator comprises an oxime compound.

5. The colored curable composition for a color filter according to claim 1, further comprising an aliphatic polyfunctional mercapto compound.

6. The colored curable composition for a color filter according to claim 1, wherein the compound represented by formula (I) is a compound represented by the following formula (IV): 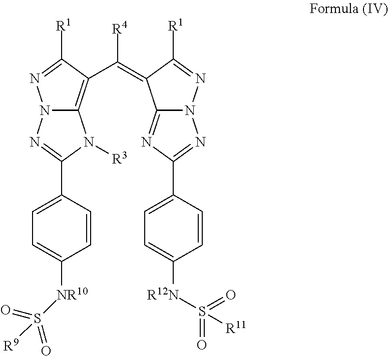
wherein, in formula (IV), R¹, R³, and R⁴ have the same definitions as R¹, R³, and R⁴ in formula (I), respectively; each of R⁹ and R¹¹ independently represents an alkyl group, an aryl group, or a heteroaryl group; and each of R¹⁰ and R¹² independently represents a hydrogen atom or an alkyl group.

7. The colored curable composition for a color filter according to claim 1, wherein the compound represented by formula (II) is a compound represented by the following formula (V): 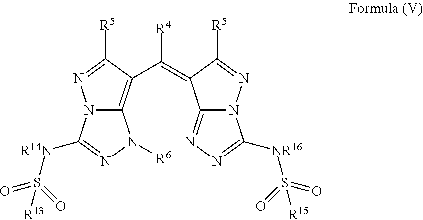
wherein, in formula (V), R⁴, R⁵, and R⁶ have the same definitions as R⁴, R⁵, and R⁶ in formula (II), respectively; each of R¹³ and R¹⁵ independently represents an alkyl group, an aryl group, or a heteroaryl group; and each of R¹⁴ and R¹⁶ independently represents a hydrogen atom or an alkyl group.

8. The colored curable composition for a color filter according to claim 6, wherein each of R⁹ and R¹¹ in formula (IV) independently represents an alkyl group having 2 to 8 carbon atoms or a substituted alkyl group having a (meth)acrylic group on an alkyl chain.

9. The colored curable composition for a color filter according to claim 2, further comprising (D) a photopolymerization initiator.

10. The colored curable composition for a color filter according to claim 9, wherein the (D) photopolymerization initiator comprises an oxime compound.

11. The colored curable composition for a color filter according to claim 10, further comprising an aliphatic polyfunctional mercapto compound.

12. The colored curable composition for a color filter according to claim 11, wherein the compound represented by formula (I) is a compound represented by the following formula (IV), and the compound represented by formula (II) is a compound represented by the following formula (V): 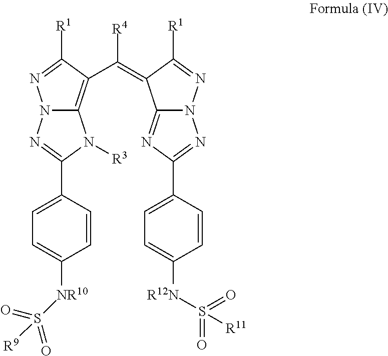
wherein, in formula (IV), R¹, R³, and R⁴ have the same definitions as R¹, R³, and R⁴ in formula (I), respectively; each of R⁹ and R¹¹ independently represents an alkyl group, an aryl group, or a heteroaryl group; and each of R¹⁰ and R¹² independently represents a hydrogen atom or an alkyl group; and: 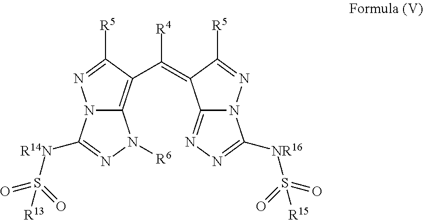
wherein, in formula (V), R⁴, R⁵, and R⁶ have the same definitions as R⁴, R⁵, and R⁶ in formula (II), respectively; each of R¹³ and R¹⁵ independently represents an alkyl group, an aryl group, or a heteroaryl group; and each of R¹⁴ and R¹⁶ independently represents a hydrogen atom or an alkyl group.

13. A colored cured film, formed from the colored curable composition according to claim 1.

14. A method for producing a color filter, comprising:
applying the colored curable composition according to claim 1 onto a substrate to form a colored curable composition layer; and
patternwise exposing and developing the formed colored curable composition layer.

15. A color filter, comprising the colored cured film according to claim 13.

16. A color filter, produced by the method for producing a color filter according to claim 14.

17. A display device, comprising the color filter according to claim 15.

18. The display device according to claim 17, further comprising an LED backlight having a peak wavelength of light emission intensity within a wavelength range of from 430 nm to 470 nm.
